(19) United States
(12) Patent Application Publication
(10) Pub. No.: US 2026/0341326 A1
(43) Pub. Date: Oct. 29, 2026

(54) 3D-DRAM WITH TIER BASED REFRESH GROUPING

(71) Applicant: Micron Technology, Inc., Boise, ID (US)

(72) Inventors: Simon J. Lovett, Nampa, ID (US); Makoto Kitagawa, Folsom, CA (US)

(73) Assignee: Micron Technology, Inc., Boise, ID (US)

(21) Appl. No.: 19/555,977

(22) Filed: Mar. 4, 2026

Related U.S. Application Data
(60) Provisional application No. 63/793,882, filed on Apr. 24, 2025.

(51) Int. Cl. G11C 11/403

(52) U.S. Cl. CPC G11C 11/403

(57) ABSTRACT

A 3D memory device uses tier-based refresh grouping. The memory array includes memory cells in a 3D array with different tiers representing different depths within the array. The memory device may group different ranges of tiers together and refresh those groups at different rates. For example, word lines in groups closer to a ‘top’ of the 3D array may be refreshed more frequently than groups closer to the ‘bottom’ of the 3D array. The relative rate of refresh of the different groups may be based on a lowest capacitance memory cell(s) of each group.

### CROSS REFERENCE TO RELATED APPLICATIONS

This application claims the benefit under 35 U.S.C. § 119 of the earlier filing date of U.S. Provisional Application Serial No. 63/793,882 filed Apr. 24, 2025. The aforementioned application is incorporated herein by reference, in its entirety, for any purpose.

### BACKGROUND OF THE INVENTION

Memory devices, such as DRAM devices have generally decreased in size and increased in capacity over time. Many of these gains have been accomplished by miniaturizing circuits such as the sense amplifier, sub-word line driver, and so for forth across different generations of memory devices. However, it is difficult to decrease the size of components below certain size thresholds, which makes it difficult to continue to improve memory device capacity and size in this manner.

It may be possible to increase memory device size and capacity by arranging memory cells in a three dimensional grid instead of a two-dimensional array. For example, multiple memory chips may be stacked on top of each other. However, this increases the thickness of the overall memory device to an extent that may be difficult to accommodate and the number of stacked chips is limited by concerns such as the length of signal lines through the stack, alignment of timing signals, and so forth. Other technologies may be used to generate 3D arrays of memory cells, such as the 3D arrays found in flash memory, but these may have limitations in the speed at which the memory device operates and are generally much slower than the speeds required of a DRAM device. There may be a need for 3D memory devices which operate at high speeds.

### BRIEF DESCRIPTION OF DRAWINGS

FIG. 1 is a block diagram of a 3D memory device according to some embodiments of the present disclosure.

FIG. 2 is a perspective drawing of a memory device with an inset showing a ‘top down’ view of an example memory quilt according to some example embodiments of the present disclosure.

FIG. 3 is a perspective schematic diagram of a portion of a 3D memory array according to some embodiments of the present disclosure.

FIG. 4 is a perspective view of a memory quilt of a memory device according to some embodiments of the present disclosure.

FIG. 5 is a top-down view of a memory quilt according to some embodiments of the present disclosure.

FIG. 6 is a cross sectional view of a memory device according to some embodiments of the present disclosure.

FIG. 7 is a cross sectional view of a memory device according to some embodiments of the present disclosure.

FIG. 8 is a cross sectional view of a memory device according to some embodiments of the present disclosure.

FIG. 9 is a block diagram of an example cross section of a 3D memory patch with refresh groups according to an embodiment of the present disclosure.

FIG. 10 is a block diagram of refresh address counter with tier based refresh grouping according to some embodiments of the present disclosure.

FIG. 11 is a chart showing an example implementation of different refresh rates for different tier groups according to some embodiments of the present disclosure.

FIG. 12 is a flow chart of a method of refreshing a 3D memory device with tier based refresh groups according to some embodiments of the present disclosure.

FIG. 13 is a flow chart of a method of tier based refreshing according to some embodiments of the present disclosure.

### DETAILED DESCRIPTION OF THE INVENTION

The following description of certain embodiments is merely exemplary in nature and is in no way intended to limit the scope of the disclosure or its applications or uses. In the following detailed description of embodiments of the present apparatuses, systems, methods, and combinations thereof, reference is made to the accompanying drawings. The drawings are shown by way of illustration of specific example embodiments of how the described apparatuses, systems, methods, or combinations thereof may be practiced. These embodiments are described in sufficient detail to enable those skilled in the art to practice presently disclosed apparatuses, systems, methods, and combinations thereof, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A 3D memory device includes a memory array. The memory array includes a number of memory cells which store information. For example, each memory cell may store a single bit of information as a charge on a capacitive element. In a conventional 2D memory device, the memory cells are logically organized in a 2D grid at the intersection of rows and columns. Conductive elements known as word lines couple memory cells along a row, and conductive elements known as digit lines or bit lines couple memory cells along a column to a sense amplifier. Accordingly, a row address may be used to specify a word line and a column address may be used to specify one or more of the digit lines.

In a 3D memory array, the memory cells are organized in a 3D array, at the intersection of word lines extending in an x direction and local digit lines extending in a z direction. Sets of local digit lines are coupled to a sense amplifier by global digit lines, which extend in a y direction. In a ‘top down’ view of an xy plane, the 3D device will somewhat resemble a 2D memory array, with a top layer, or top tier, of memory cells at the intersection of word lines and global digit lines, however in addition the 3D array has multiple tiers of memory cells extending in the z direction which are coupled together by the local digit lines. The present disclosure will generally use the convention that word lines extend along an x direction, global digit lines extend along a y direction, and local digit lines extend along a z direction, where x y and z are mutually orthogonal axes.

Much like a conventional DRAM device, the memory cells of a 3D device may lose information over time. For example, due to leakage of the charge on the capacitive element. To prevent information loss, the memory device may be periodically refresh. Over the course of a refresh period, each of the memory cells is refreshed. For example, a specification of the memory device may require a certain number of refresh commands be issued over the course of a refresh period. Responsive to the refresh command the memory performs one or more refresh operations. As part of a refresh operation, the memory generates a refresh address and refreshing one or more word lines associated with the refresh address. The memory may also perform self-refresh operations in an analogous fashion by activating a self-refresh oscillator and performing refresh operations responsive to the self-refresh oscillator signal. The timing of refresh operations may generally be set based on an expected worst case retention time of the memory cells. The use of a 3D array may allow for add variability in retention time that gives the opportunity for a more tailored approach to the rate at which cells get refreshed.

The present disclosure is drawn to apparatuses, systems, and methods for 3D memory devices with tier based refresh grouping. As part of the manufacturing process of a 3D memory array, certain memory cells may have different capacitance values. For example, capacitance may generally increase as a function of tier, with memory cells at lower tiers (e.g., further from the global digit lines) having a higher capacitance than memory cells at higher tiers (e.g., closer to the global digit lines). Retention time may generally scale with capacitance, so the retention time may generally increase with tier from top to bottom. The 3D memory device may use refresh grouping by tier. A group of memory cells which are at a higher tier may be refreshed more frequently than a group of memory cells at a lower tier.

In some implementations, the overall rate of refresh operations (e.g., the number of refresh commands/self-refresh signals per refresh period) may average out to match the operation of a conventional device. In this way, there is improved retention characteristics, since the memory cells with the weaker retention (e.g., the ones in the higher group) are receiving more refreshes without an overall increase in required refreshes, since the memory cells with greater retention (e.g., the ones in the lower group) do not require as many refreshes.

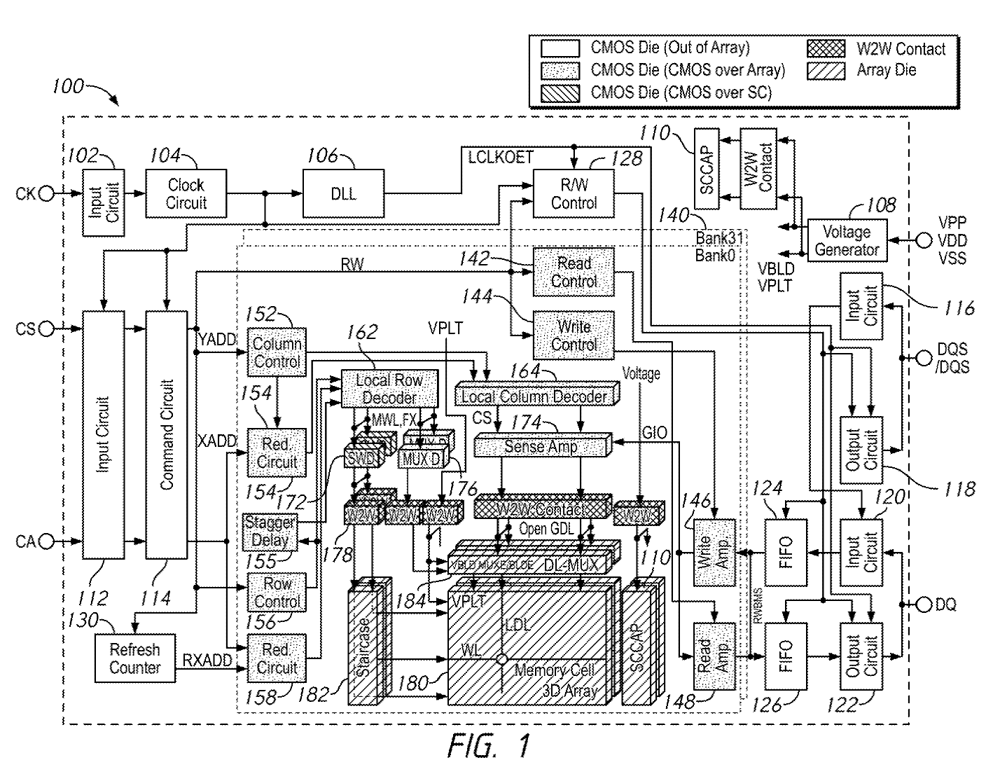

FIGS. 1-8 are generally described with respect to a particular example layout of a 3D memory device with a folded digit line architecture for the global digit lines and a particular spatial arrangement of components in the CMOS die above the array. However, the tier based refreshing described herein may be used with other example layouts. For example, tier based refreshing may be performed in a 3D memory device with an open digit line architecture for the global digit lines, with different spatial arrangements of components, or combinations thereof.

FIG. 1 is a block diagram of a 3D memory device according to some embodiments of the present disclosure. The view of the 3D memory device 100 in FIG. 1 is a block diagram representing the different components of the 3D memory device 100. It does not represent the spatial layout of the components of the device, except where otherwise noted.

The 3D memory device 100 may be coupled to a controller (not shown in FIG. 1) which provides various commands, data, and other signals to the memory device 100 to operate the memory. In some embodiments, the 3D memory device 100 may be a stand-alone device. In some embodiments the 3D memory device 100 may be part of a module that packages together several similar memory devices.

The 3D memory device 100 includes a number of external terminals which receive various signals which are used by the device 100. The signals which are received, as well as the signals within the memory device 100, are generally represented by voltages, which different levels of voltage representing different states of the signal. For example, many of the signals used by the memory device 100 may be binary signals, where a first voltage level represents a logical high and a second voltage level represents a logical low. Example terminals include a clock terminal CK, a chip select terminal CS, a command/address terminal CA, data strobe terminals DQS and /DQS, data terminals DQ, and voltage terminals such as VPP, VDD, and VSS. Any of those example terminals may include one or more individual terminals.

The clock signal CK is received by the clock terminal and provided through an input circuit 102 to a clock circuit 104. The clock signal CK is used to control the timing of operations in the memory device 100. The clock circuit 104 generates one or more internal clock signals based on the external clock signal CK and distributes them to various other components of the memory device 100. The clock circuit 104 also provides the clock signal to a delay locked loop (DLL) circuit 106 which generates a delayed clock signal LCLKOET. The delayed clock circuit may be used to match a timing it takes the clock signal to propagate through the memory device 100 and may be used to time read operations. The 3D memory device 100 also receives and provides data strobes DQS and /DQS through a respective input circuit 116 and output circuit 118. During write operations the memory receives a data strobe signal used to time operations of the input circuit 120 for the data DQ. During read operations the memory 100 provides the delayed clock signal LCLKOET to time the operations of a data output circuit 122 to the data terminal DQ. Buffer circuits 124 and 126 are used to serialize or deserialize data between the memory device and the DQ terminals.

The memory device 100 receives voltages at voltage terminals. The voltages are provided to a voltage generator circuit 108 which generates one or more internal voltages based on the provided voltages. The provided voltages as well as the generated voltages are distributed to the various circuits of the memory device 100. For example, the memory device 100 may receive a ground voltage VSS and a system voltage VDD as well as a voltage VPP. The memory includes SC capacitors 110 which help regulate voltages in the memory array 180. The SC capacitors or SCCAPs 110 are located in the memory array 180 and are coupled to the voltage generator circuits 108 through wafer contacts in some embodiments.

The memory receives commands and addresses along a command/address bus coupled to CA terminals. The 3D memory device 100 also receives a chip select signal CS, which is used to time signals along the CA terminals, as well as indicate which memory device 100 is receiving commands and addresses in embodiments where multiple memory devices are packaged together. The CS and CA signals are passed through an input circuit 112 to a command/address circuit 114. Examples of addresses include bank address BADD which specifies a bank of the memory device 100, row address XADD which specifies a row of the device, and column address YADD which specifies a column of the device. Examples of commands include activation commands ACT, pre-charge commands PRE, access commands such as read R or write W, or refresh commands. Certain commands and addresses may generally be received together. For example the CA terminal may receive a row activation command ACT along with a row address XADD and bank address BADD. Access commands such as read or write may generally be received along with a column address YADD. A read/write control circuit 128 helps manage the RW commands.

The 3D memory device 100 is divided into one or more memory banks 180. In the embodiment of FIG. 1, there are 32 banks, labelled Bank0 to Bank31. More or fewer banks may be used in other example embodiments. Each bank is associated with a bank logic region 140, which includes the memory array 180 of the bank as well as various circuits associated with that bank. These circuits may generally be repeated on a bank-by-bank basis. An example bank logic region 140 may include a column control circuit 152 and column redundancy circuit 154, a row control circuit 156 and row redundancy circuit 158, local row decoder 162, local column decoder 164, sub-word line drivers 172, sense amplifiers 174, multiplexer drivers 176, the array 180 and staircase region 182, digit line multiplexers 184, write amplifiers 146 and read amplifiers 148.

The array 180 is a 3D array with memory cells coupled at the intersection of word lines WL and local digit lines LDL. The view of FIG. 1 shows an example slice of the array through an xz plane, showing an example WL and LDL. The LDLs are coupled together along a y axis by pairs of global digit lines GDL. The pair of GDLs coupled to a same sense amplifier of the sense amplifiers 174. Along the length of the GDL pair, a portion (e.g., a first half) of the LDLs are coupled to one GDL in the pair, and a portion (e.g., a second half) of the LDLs are couple to the other GDL in the pair. In some embodiments, multiplexers 184 are used to select which of the intersecting LDL(s) are coupled to the respective GDL, and through that GDL to the sense amplifier. The local row decoder 162 is used to selectively activate multiplexer drivers 176 based on the row address, which activates respective ones of the multiplexers 184. In some embodiments, the multiplexers 184 and their respective drivers 176 may not be used and may be eliminated.

The row control circuit 156 activates a word line of the memory array 180 based on the row address. The row control circuit 156 provides internal signals to the local row decoder circuits 162. The local row decoder circuit 162 activates a sub-word line driver 172 associated with the word line specified by XADD. The sub-word line driver 172 is coupled to an associated word line WL through the staircase 182. The sub-word line driver selected by the row address activates the associated word line, causing the memory cells along that word line to couple to the intersecting local digit lines LDLs. The LDLs are coupled to one of each of the intersecting pairs of GDLs. The sense amplifier compares the signal along the GDL of the pair coupled to the active word line (through the LDL) to a reference along the GDL of the pair which is not coupled to the active word line. In some embodiments, the local row decoder circuit 162 also activates a multiplexer driver 176 which in turn selects multiplexers 184 to couple the LDLs which intersect the selected word line to the GDLs.

The multiplexers 184 may be an optional component used in some example embodiments. In embodiments where multiplexers are used, the local row decoder circuit 162 receives the row address XADD and uses the row address to determine which multiplexer(s) 176 to activate. Based on the row address the local row decoder circuit 162 provides decoded address to the multiplexer drivers 176, and the multiplexer driver(s) associated with the decoded address provide a multiplexer driver signal. The multiplexers 176 may be grouped together in sets, and the sets are coupled in common to a multiplexer driver 176 provides the multiplexer driver signal, the multiplexers in the set are activated and couple the associated LDL to the respective GDL of the GDL pair. In some embodiments, when the multiplexer driver signal is inactive, the LDL may be decoupled from the GDL and coupled to a ground voltage instead.

A stagger delay circuit 155 controls a timing of the operation of the local row decoder circuit 162. For example, the stagger delay circuit 155 may use internal signals to control when the local row decoder circuit 162 activates the SWD 172 and when it activates the multiplexer driver 176.

The column control circuit 152 selects which global digit lines to couple to global input/output lines GIO based on the column address YADD. During a write operation, the GIO lines are coupled to a write amplifier 146, which provides data received from the input circuit 120 through the GIO lines to the selected GDL lines and through those to the memory cells at the intersection of the selected WL and LDL. During a read operation, the data from the memory cells at the intersection of the selected WL and LDL are coupled through the selected GDL to the read amplifier 148, which provides the read data to the output circuit 122.

The memory bank logic region 140 also includes redundancy circuits 154 and 158. The redundancy circuits 154 and 158 are used as part of repair operations. If a row or column address has been repaired, the redundancy circuits 154 or 158 will direct access to a redundant word line or redundant column.

In an example write operation, data received along the DQ terminals is written to specified memory cells of the 3D memory device 100. The device 100 receives a row activation command along with a row address. The local row decoder 162 selects SWDs 172 to activate the associated word line based on the row address and may activate a multiplexer driver 176. The device 100 receives a write command along with a column address. Data is received by the input circuit 120 and deserialized by a buffer circuit 124 which provides the data to write amplifiers 146. The local column decoder 164 couples selected global digit lines to the GIO lines based on the column address YADD. In some embodiments, a multiplexer driver 176 is activated by the local row decoder 166 and couples a local digit line which intersects the active word line to the respective global digit lines. The data from the write amplifier 146 is written along the GIO lines to GDL line, onto the selected LDL lines and into the memory cells at the intersection of the LDL with the active word line WL.

In an example read operation, data from the array 180 is provided out along the DQ terminals. The device 100 receives a row activation command along with a row address. The local row decoder 162 selects SWDs 172 to activate the associated word line based on the row address. In some embodiments, the global row decoder 166 selects a multiplexer driver 176 to selectively couple one or more selected LDLs to the respective GDL. Data is read out from the memory cells which intersect the active word line through the intersecting LDLs and along the GDLs. The device 100 receives a read command along with a column address. Data is read out from selected ones of the GDLs along the GIO lines to a read amplifier 148. The read amplifier provides the read data to a buffer 126 which serializes the data and provides the serialized data to the output circuit 122.

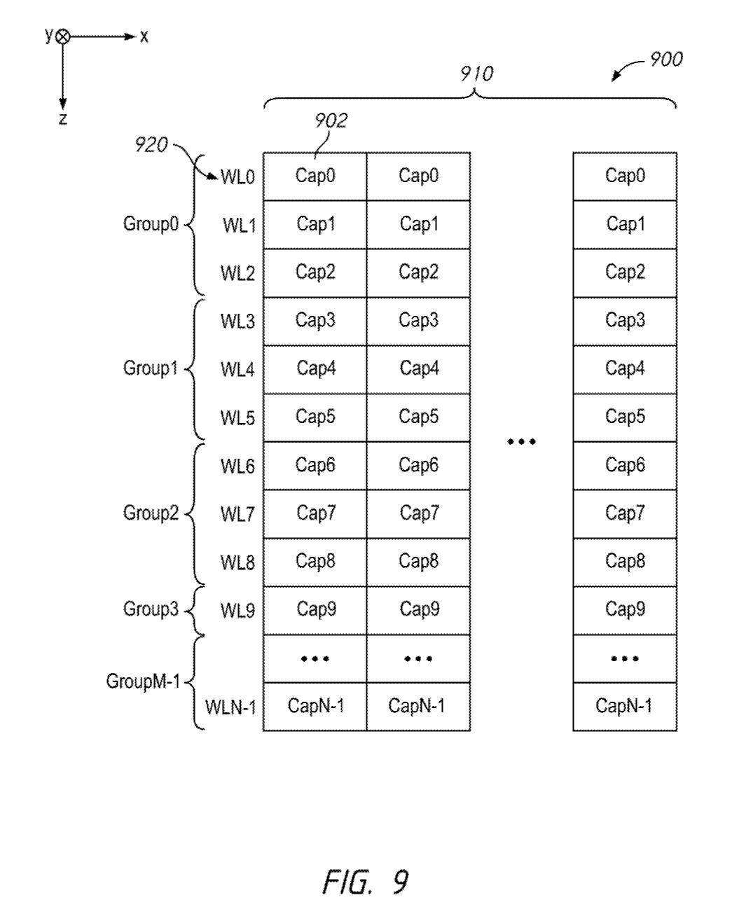

The 3D memory device 100 may also perform refresh operations. As part of a refresh operation, one or more word lines have the data in the intersecting memory cells refreshed. For example, the memory cells may store information as charge on a capacitive element, and that charge may decay over time. A refresh operation restores that charge to a nominal value. Responsive to a refresh command, a refresh counter circuit 130 provides one or more refresh addresses RXADD which specify which word line or word lines should be refreshed. The refresh counter circuit 130 may divide the 3D memory array 180 into one or more refresh groups based on a depth of the memory cells within the array. Tier-based refresh grouping is described in more detail in FIGS. 9-13, below.

FIG. 1 generally shows the 3D memory device 100 as a flattened 2D drawing. However certain components may be positioned over other components in an example implementation. For example, the bank logic circuits 140 may be positioned ‘above’ (in the z direction) the memory banks 180. For example, the sub-word line drivers 172 may be positioned above the staircase 182. In some embodiments, the memory device 100 may be printed on two chips, which are then bonded together. For example, components such as the array 180, staircase 182 and digit line multiplexers 184 may be printed in an array die, while the other components are printed on a CMOS die. A set of wafer to wafer (W2W) contacts 178 couple the CMOS die to the array die. In some embodiments, certain components may be positioned above the memory array. For example, at least some of the sense amplifiers 174 may be positioned above the array 180.

The present disclosure will generally be described with respect to an example implementation where two chips are used, however other implementations using more or fewer chips may also be used, and other arrangements of components between chips may be used.

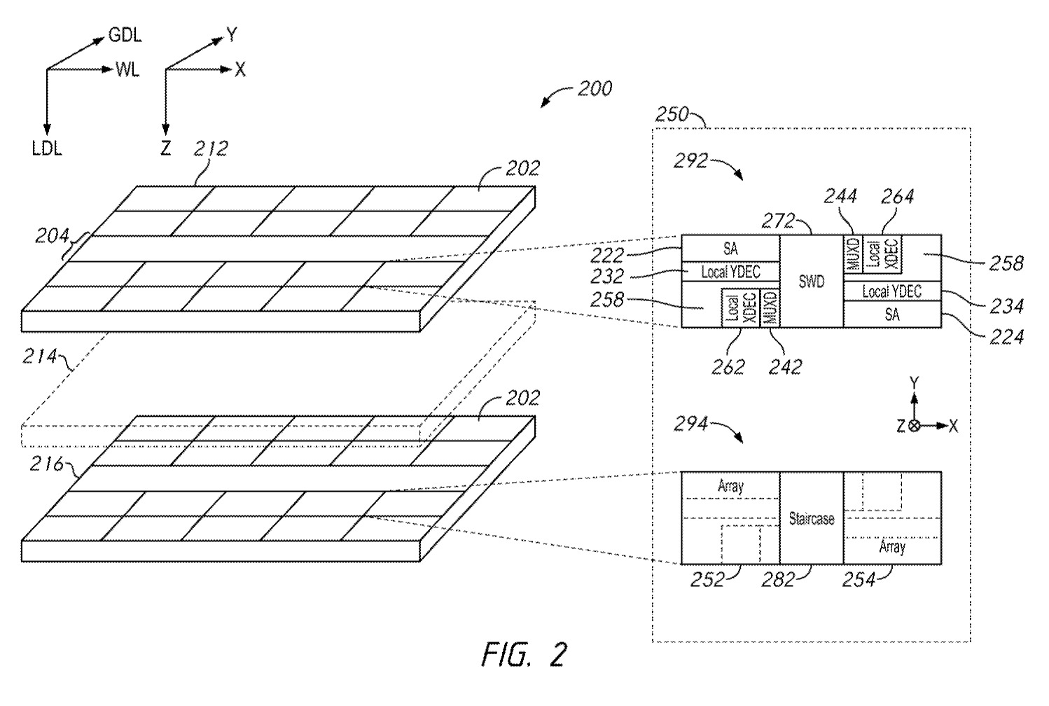

FIG. 2 is a perspective drawing of a memory device with an inset showing a ‘top down’ view of an example memory quilt according to some example embodiments of the present disclosure. The memory device 200 may, in some embodiments, represent a layout which implements the 3D memory device 100 of FIG. 1.

The memory device 200 includes a number of memory quilts 202, each of which includes one or more portions of memory array, such as memory patches, as well as circuitry which supports the operation of those patches such as SAs (e.g., 174 of FIG. 1) and SWDs (e.g., 172 of FIG. 1). The memory quilts 202 are tiled in the x-y plane of the memory die 200. The memory quilts 202 are sections of the memory array. They may be referred to as quilts herein, because when considered in the xy plane the repeating patterns of circuits tiled across surface of the device are evocative of quilt patches. The memory device 200 also includes a peripheral region 204, which does not have memory quilts 202 tiled across it. The peripheral region 204 may include other circuits which are used in the operation of the memory such as the command circuit 114 of FIG. 1, the input and output circuits 116-122 of FIG. 1 and other components.

The memory device 200 is formed from two die, a first die 212 and a second die 216. The first die 212 is stacked on top of the second die 216 in the z-direction. The first die 212 may be a die which includes various circuits and components which operate the memory device 200, while the second die 216 may be an array die which includes the memory cells, word lines, local digit lines and global digit lines. The second die 216 may also include components which are used to couple components together such as the staircase. The first die 212 may generally be referred to as a CMOS die and the second die 216 may generally be referred to as an array die.

The two die 212 and 216 may be bonded together. For example, wafer-to-wafer (W2W) bonding may be used. A bottom surface in the z direction of the first die 212 may have one or more connection points such as bumps. A top surface in the z direction of the second die 216 may have corresponding connection points such as bumps. When the two die are bonded, the connection points may be electrically coupled between corresponding bumps. In some embodiments, an optional bonding layer 214 between the two die may be used.

In the example of FIG. 2, the peripheral region 204 extends across a width of the two die 212 and 216 in an x-direction, and a portion of the surface of the dice 212 and 216 in the y-direction. The peripheral region 204 is generally centered in the device along the y-axis. The device 200 has memory sections 202 positioned in a grid layout above in the +y direction and below in the -y direction the edges of the peripheral region 204. Other arrangements of the peripheral region 204 and quilts 202 may be used in other example embodiments. FIG. 2 shows a simplified view with a 2x5 grid of quilts 202 on either side of the peripheral region 204. However, more or fewer quilts 202, or different arrangements of quilts 202 may generally be used in other example embodiments. For example, an implementation of a memory device may generally be expected to include many more quilts 202 than the twenty sections illustrated in FIG. 2.

Both die 212 and 216 have memory quilts 202 which have respective portions tiled across the surface of the two die. Each memory quilt 202 has a portion 292 on the first die 212 and a portion 294 on the second die 216. The portions 292/294 of a given memory quilt 202 across the two die are vertically stacked so they align in an x-y plane and are stacked in the z direction.

The inset 250 shows a ‘top down’ view in the xy plane of a quilt 202. The quilt 202 includes two memory patches 252 and 254. Each memory patch 252 and 254 includes a 3D array of memory cells at the intersection of word lines and local digit lines, with the local digit lines coupled together by global digit lines. As well as the memory patches 252 and 254, the quilt 202 also includes sense amplifier portions 222 and 224, local column decoder 232 and 234, multiplexer driver regions 242 and 244, local row decoders 262 and 264, sub-word line driver region 272, and staircase region 282. The sense amplifier portions 222 and 224, local column decoder 232 and 234, multiplexer driver regions 242 and 244, local row decoders 262 and 264, and sub-word line driver region 272 are located in the portion 292 on the first die 212. The array patches 252 and 254 and the staircase region 282 are located in the second portion 294 in the second die 216.

The portion 292 of the quilt 202 in the first die 212 also includes spacer regions 258, located on either side of the SWD region 272. These spacer regions 258 are located above the memory array patches 252-257 in the z direction. The spacer regions 258 may be regions of the first die 212 which are generally empty of circuits in some embodiments.

The example layout of the quilt 202 shown in the inset 250 may be used for each of the quilts 202. The patches 252 and 254 may be generally thought of as rectangular prisms, with a ‘top’ of the prism in the xy plane shown in the inset 250. Each patch 252 and 254 is also elongated along the z-axis, which is not shown in the ‘top down’ view of FIG. 2A. The two patches 252 and 254 may have generally the same dimensions as each other. The staircase region 282 is positioned between the two array patches 252 and 254 such that the staircase region 282 separates the two patches 252 and 254 along the x axis. Like the memory patches, the staircase region 282 may be thought of as a rectangular prism elongated in the x, y and z directions. The staircase may have generally the same height in the y axis as the two adjacent memory patches 252 and 254.

The SWD region 272 is positioned above the staircase region 282. The SWD region 272 may generally have the same x and y dimensions as the staircase region 282. Each spacer region 258 is positioned above a corresponding one of the array patches 252 and 254. Each of the patches 252 and254 has an associated sense amplifier region, local column decoder, multiplexer driver region, and local row decoder. For example, the array patch 252 is associated with sense amplifier region 222, local column decoder 232, multiplexer driver 242 and local row decoder 262, while the array patch 254 is associated with sense amplifier region 224, local column decoder 234, multiplexer driver 244 and local row decoder 264.

The sense amplifiers are positioned above the patches 252 and 254 they are associated with. For example, the sense amplifier region 222 is above the patch 252 and the region 224 is above the patch 254. Each of the sense amplifiers in the region is coupled to the respective global digit lines via vertical conductive elements run in the z direction down from the first die 212 to the second die 216. Each sense amplifier may be coupled to a pair of global digit lines in the respective memory patch. In some embodiments, each sense amplifier region 222/224 includes sense amplifiers arranged in a grid in the xy plane.

The sense amplifier regions 222 and 224 may be above a portion of the associated memory patch 252 and 254. For example, the sense amplifier regions may generally have a same width in the x direction as the memory patches 252/254, but a shorter height in the y direction. The two sense amplifier regions 222 and 224 may be aligned with opposite edges of the memory patches. For example, an upper (in the y direction) edge of the sense amplifier region 222 is aligned with an upper edge of the memory patch 252, while a lower edge of the sense amplifier region 224 is aligned with a lower edge of the memory patch 254.

Each sense amplifier region 222 and 224 is associated with a respective local column decoder 232 and 234 (e.g., 164 of FIG. 1). During operations, the local column decoders 232/234 use the column address to determine which global digit lines are coupled outside of the array along the global input/output (GIO) lines. The local column decoders 232/234 are positioned over the array, next to the associated sense amplifier region. For example, the local column decoders 232/234 may be along an ‘interior’ edge of the associated sense amplifier region. For example, the sense amplifier region 222 has an upper edge aligned with an upper edge of the patch 252, and the associated local column decoder 232 along its lower edge.

The multiplexer drivers are positioned above the patches 252 and 254 they are associated with. For example, the multiplexer driver region 242 is above patch 252 and the multiplexer driver region 244 is above the patch 254. An edge of the multiplexer driver regions 242/244 is aligned with an edge of the SWD region 272. For example, a right (in the x direction) edge of the multiplexer driver region 242 borders a left edge of the SWD region 272, and a left edge of the multiplexer driver region 244 borders a right edge of the SWD region 272. Each of the multiplexer driver regions has an associated local row decoder 262/264 (e.g., 162 of FIG. 1) which is along an edge of the multiplexer driver region 242/244 opposite the edge which borders the SWD region. For example, the multiplexer driver region 242 borders the SWD region 272 along itsright edge and the associated local row decoder 262 along its left edge. The multiplexer driver regions 262/264 are opposite the sense amplifier regions 222/224. For example, an upper edge of the sense amplifier region 222 is aligned with an upper edge of the patch 252, and a lower edge of the multiplexer driver region 242 is aligned with a lower edge of the patch 252.

The memory array patches 252 and 254 represent a piece of the 3D array. For example, each memory patch 252-257 includes memory cells positioned at the intersection of word lines extending along the x axis and local digit lines extending in the z direction, which is into the plane of the page in the view of the inset 250. The local digit lines are coupled together in columns running in the y direction by global digit lines.

The word lines extend between two of the patches 252 and 254. For example, a word line may be continuous across the width of the array patch 252, through the staircase region 282 and across the width of the array patch 254. The word lines intersect memory cells in the array patches, but not in the staircase region when passing through the staircase region 282. For example, a word line intersects local digit lines and memory cells in the array patch 252, then passes through the staircase region 282 without intersecting memory cells or LDLs, and then intersects LDLs and memory cells again in the array patch 254. In other words, when considered along its length in the x direction, each word line has a gap where there are no coupled memory cells in the staircase region.

The SWD regions 272 and 276 include a number of SWDs, each of which is coupled to a respective word line which extends across both of the associated array sections 252/254 through the staircase region 282. For example, a first SWD in the region 272 is coupled to a first word line which extends across both array patches 252 and 254, a second SWD in the region 272 is coupled to a second word line which extends across both array patches 252 and 254, and so forth. The SWDs in the SWD region 272 are arranged in a grid, which has dimensions based on the number and arrangement of word lines in the adjacent memory patches 252/254. For example, if there are M word lines in the y-direction and N word lines in the z direction across the two patches 252/254 for a total of NxM word lines in the two patches, then there will also be NxM SWDs in the region 272. For example, the region 272 may have a grid of SWDs with M SWDs in the y-direction and N SWDs in the x direction. Along a given row in the x direction, each SWD couples to a different depth of word line in the z-direction using a connective element which extends along the z-direction to the associated word line.

The global digit lines in the array patches 252 and 254 are coupled to sense amplifiers in the associated sense amplifier portions 222 and 224. The global digit lines in the patch 252 are coupled to sense amplifiers in the region 222 and the global digit lines in the patch 254 are coupled to sense amplifiers in the region 224. Each sense amplifier is coupled to two global digit lines, both in the same patch. For example, each sense amplifier may be coupled to a pair of global digit lines which are adjacent to each other. In some embodiments, the pair of global digit lines may be stacked on top of each other in the z direction. For example they may run in different metal layers. This layout may be referred to as a folded architecture, since the two digit lines run in a same direction (e.g., both run in the +y direction or in the -y direction) away from the sense amplifier. One of the pair of global digit lines is referred to as a ‘true’ global digit line or GDLT and the other is referred to as a ‘bar’ global digit line GDLB. Along the pair of GDLs, some local digit lines are coupled to GDLT and some are coupled to GDLB. During operations, one of the GDLT and GDLB is used to carry a signal to or from a memory cell and one is used as a reference by the coupled sense amplifier, depending on which word line is activated.

In some embodiments, the sense amplifiers within a region may be arranged in a grid. For example, if there are L global digit line pairs, there may be L sense amplifiers. The sense amplifiers may be arranged in a grid of I x J sense amplifiers, where I*J = L. The arrangement of the grid may be based, in part, on the size of the sense amplifiers in the x direction relative to the spacing of the GDL pairs in the x direction. For example, if a sense amplifier is generally as wide as four GDL pairs, then the sense amplifiers may be arranged in a grid with columns of four sense amplifiers each, with each of sense amplifier coupled to a different one of the GDL pairs than runs below that column.

In an example implementation, each of the memory patches 252 and 254 may include about 8Mbit of storage or about 8,192,000 memory cells. An example memory patch 252 has 8000 word lines arranged in a grid in the yz plane of 80 word lines in the y direction and 100 word lines in the z direction. The word lines are intersected by a grid in the xy plane of 1024x80 local digit lines with 1024 local digit lines in the x direction and 80 in the y direction. Each ‘column’ of 80 local digit lines is coupled to one or the other of a pair of associated global digit lines for a total of 1024 global digit line pairs or 2048 total global digit lines. The associated sense amplifier region 222 includes 1024 sense amplifiers, each coupled to a pair of global digit lines. The sense amplifiers may be arranged in an xy grid of 256 sense amplifiers in the x direction and 4 sense amplifiers in the y direction. Each sense amplifier is coupled to the associated GDL pair by a vertical (in the z direction) element running down to the GDL running below the sense amplifier. The SWD region 272 includes 8000 SWDs, one for each word line, arranged in a grid in the xy plane of 80 SWDs in the y direction and 100 in the x direction. The multiplexer driver region 242 includes half of the total multiplexer drivers, arranged in a column in the y direction. For example, if each multiplexer driver is coupled to a single LDL, then there are 80 total multiplexer drivers, 20 of which are in the region 242 (the other 20 are in region 244).

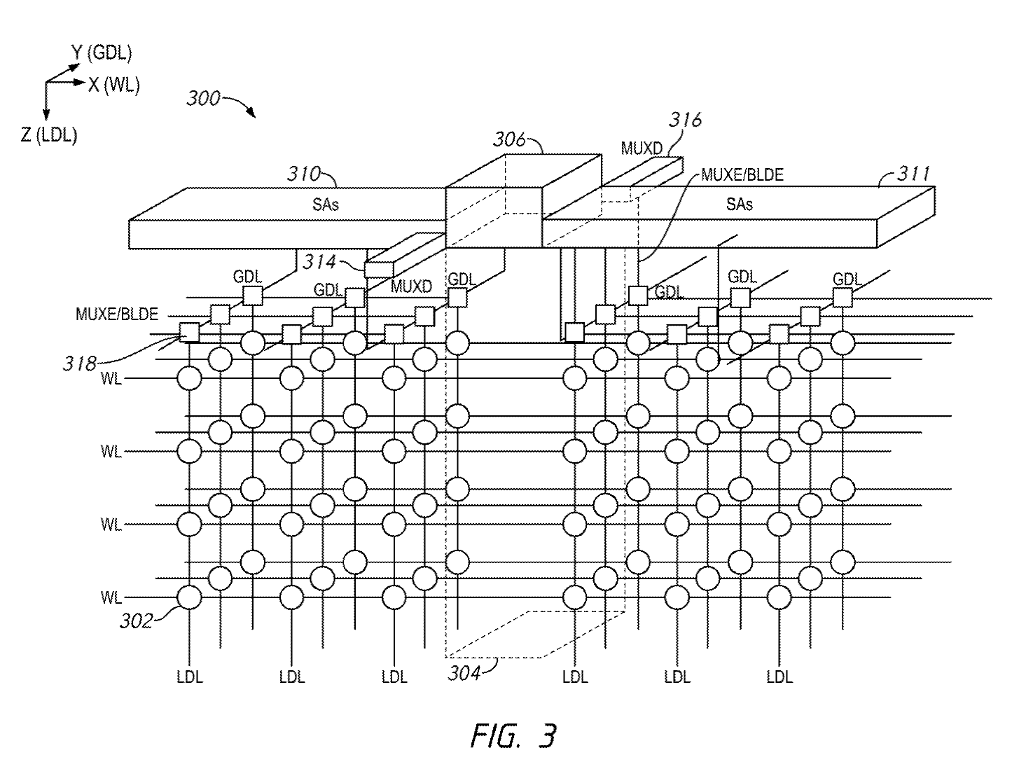

FIG. 3 is a perspective schematic diagram of a portion of a 3D memory array according to some embodiments of the present disclosure. The 3D memory array 300 represents a simplified view of an example portion of a memory array. For example, the 3D memory array 300 may represent a portion of the 3D array 180 of FIG. 1, and/or a representation of the quilt 202 of FIG. 2. The perspective of FIG. 3 shows an example set of memory cells 302 and their respective word lines, local digit lines and paired global digit lines. The view of FIG. 3 may be a simplified representational view which shows a relatively small number of word lines, global digit lines, local digit lines etc.

The memory array 300 shows memory cells 302. Each memory cell 302 is positioned at the intersection of a word line WL and a local digit line LDL. Each LDL is associated with one or the other of a pair of GDLs. The paired global digit lines are both coupled to a respective sense amplifier in the sense amplifier portions 310-311 (e.g., 174 of FIG. 1 and/or 222-224 of FIG. 2). The word lines are each coupled to a respective SWD in a SWD region 306 (e.g., 172 of FIG. 1 and/or 272 of FIG. 2). The word lines are coupled via a staircase region 304 (e.g., 182 of FIG. 1, 282 of FIG. 2) to the SWD region 306. Also shown are multiplexer driver regions 314 and 316 (e.g., 176 of FIG. 1 and/or 242-248 of FIG. 2) which couple to multiplexer circuits 318 (e.g., 184 of FIG. 1).

In some embodiments the SA regions 310-311, multiplexer drivers 314-316 and SWD region 306 may be in a different die than the die which includes the WL, LDL, GDL, memory cells 302 and multiplexer circuits 318. The view of FIG. 3 shows an example embodiment similar to the embodiment of FIG. 2, where the sense amplifier regions 310-311 are positioned above the array patches. In particular, the view of FIG. 3 may represent the patches 252 and 254 of FIG. 2, as well as their associated staircase region 282, sense amplifier regions 222 and 224, SWD regions 272, and multiplexer driver regions 242 and 246. The local column and row decoders are omitted from the view of FIG. 3.

The staircase region 304 is a 3D region, which may be generally have the form of a rectangular prism. The staircase region 304 is positioned underneath the SWD region 306 in the z-direction. In some embodiments, the staircase region 304 may have the same x-y dimensions as the SWD region 306. The staircase region 304 is positioned between two sections of the word lines WL which intersect memory cells 302. However, the WLs may not intersect any memory cells while they pass through the staircase region 304. Vertical connection elements which extend in the z direction (not shown in FIG. 3) couple each word line to a respective SWD in the SWD region 306. A middle of the word lines WL may be positioned in the staircase region 304.

The word lines WL are arranged in a grid when considered in the yz plane. Similarly, the LDLs may be arranged in a grid when considered in the xy plane. The GDLs are generally arranged in a plane side-by-side with each other.

The LDLs are selectively coupled to one of the GDLs of the associated pair of GDLs through a multiplexer circuit 318. Some of the LDLs along the length of the GDL pair are coupled to one of the GDLs in the pair and some of the LDLs are coupled to the other. For example, each GDL in the pair of GDLs may be coupled to roughly half of the LDLs along the length of the GDL pair. The multiplexers are coupled to multiplexer drivers in a multiplexer driver region 314 or 316. A line of multiplexer drivers may be coupled in common by a multiplexer driver line along the x direction to a multiplexer driver in the multiplexer driver region 314/316. The multiplexer driver provides a multiplexer enable signal MUXE. When MUXE is active, all the multiplexers 318 which are coupled in common to that signal line will couple their respective LDL to the associated GDL.

In some embodiments, the multiplexer drivers 314/316 may also provide a bleed enable signal BLDE. When the bleed enable signal BLDE is active, the multiplexer couples the respective LDL to a ground voltage. In an example operation, the multiplexer driver associated with the row address provides an active MUXE signal and an inactive BLDE signal while the multiplexer drivers which are not associated with the row address provide an active BLDE signal and an inactive MUXE signal. Accordingly, during the operation, multiplexers which receive an active MUXE couple their LDLs to the GDL, while the other multiplexers along each GDL isolate their LDLs from the GDL and instead couple them to a ground voltage so they do not float.

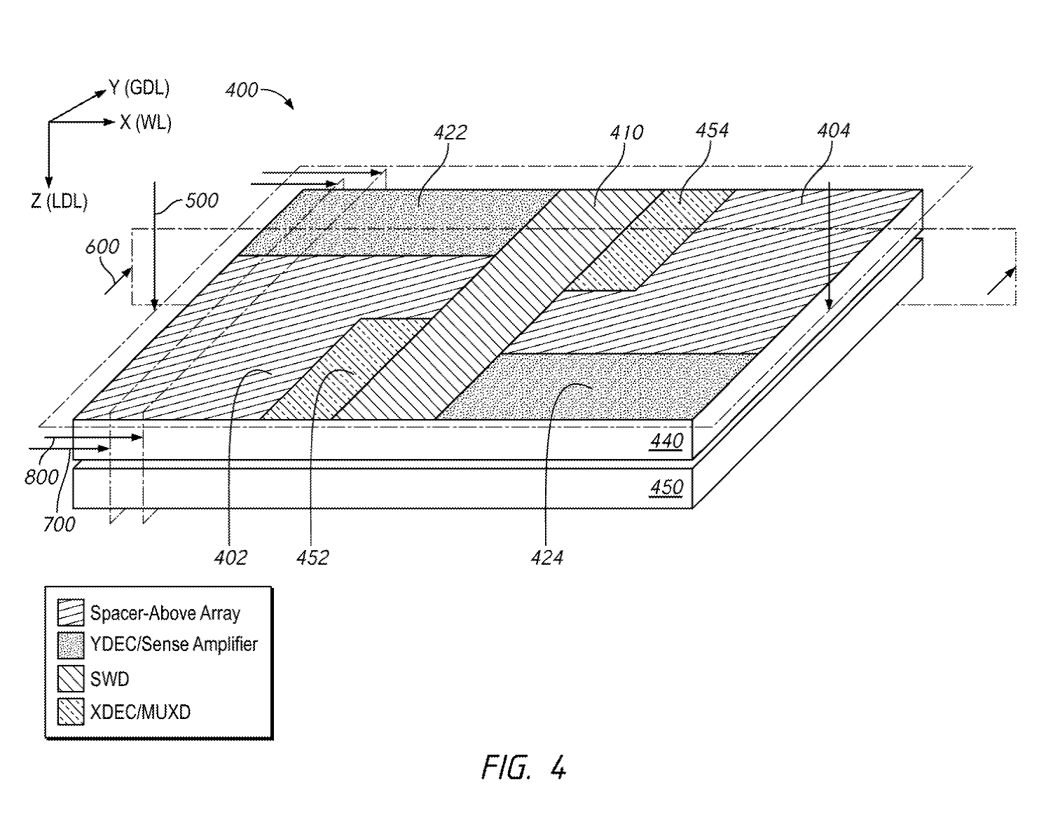

FIG. 4 is a perspective view of a memory quilt of a memory device according to some embodiments of the present disclosure. The memory quilt 400 may represent a portion of a memory device such as 100 of FIG. 1 and/or 200 of FIG. 2. The memory quilt 400 may include one or more memory arrays which have layouts similar to the memory array 300 of FIG. 3 in some embodiments. The memory quilt 400 may be generally similar to the quilt 202 of FIG. 2. However, FIG. 4 shows a perspective view rather than a ‘top down’ view of the xy plane.

The memory device which includes the quilt 400 includes a first die 440 (e.g., 212 of FIG. 2) and a second die 450 (e.g., 216 of FIG. 2). The first die 440 may includes the sense amplifiers, SWDs, and multiplexer drivers. For example the first die 440 may be a CMOS die. The second die 450 includes the memory array patches and staircase regions.

The memory quilt 400 includes a first memory patch 402 (e.g., 252 of FIG. 2), a second memory patch 406 (e.g., 254 of FIG. 2) and a SWD region 404 (e.g., 172 of FIG. 1, 272 of FIG. 2, and/or 306 of FIG. 3) in between. Each memory patch has an associated sense amplifier and column decoder region and an associated multiplexer driver and row decoder region. The patch 402 is associated with sense amplifier and column decoder region 422 (e.g., 174 and 164 of FIG. 1, 222 and 232 of FIG. 2, and/or 310 of FIG. 3) and multiplexer driver and row decoder region 452 (e.g., 176 and 162 of FIG. 1, 242 and 262 of FIG. 2, and/or 314 of FIG. 3). The patch 404 is associated with sense amplifier and column decoder region 424 (e.g., 174 and 164 of FIG. 1, 224 and 234 of FIG. 2, and/or 311 of FIG. 3) and multiplexer driver and row decoder region 454 (e.g., 176 and 162 of FIG. 1, 244 and 264 of FIG. 2, and/or 316 of FIG. 3).

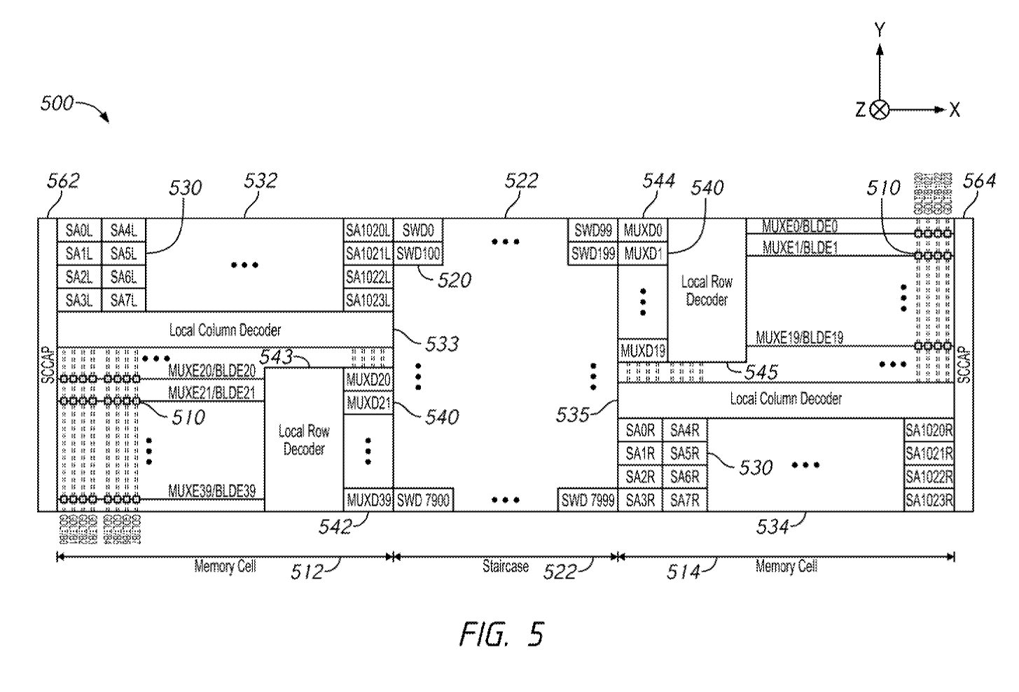

FIG. 4 shows planes 500, 600, 700, and 800 which represent the cross-sectional views of FIGS. 5, 6, 7, and 8 respectively. The plane 500 is a slice along an xy plane of the memory 400 shows the memory patches 402 and 404 as well as the sense amplifier/column decoder regions 422 and 424, the multiplexer driver/row decoder regions 452 and 454 and the SWD and staircase region 410.

The plane 600 is a slice along an xz plane of the memory which intersects a second memory patch 402, the SWD and staircase region 410 and a second memory patch 404. The plane 600 also intersects sense amplifier region 422. The plane 700 is a slice along a yz plane which intersects the first memory patch 402 and the sense amplifier region 422. The plane 800 is a similar yz slice to the plane 700 except that the plane 800 is slightly offset from the plane 700 in the x direction.

FIGS. 5-8 show different cross-sectional views of the memory device 400 of FIG. 4. Each of FIGS. 5-8 is illustrated with respect to an example embodiment where each memory patch such as 402 and 406 includes 8 Mbit of memory cells. Specifically, they are shown to include a grid of 80 word lines in the y direction and 100 word lines in the z direction, a grid of 80 LDLs in the y direction and 1024 LDLs in the x direction, and 1024 pairs of global digit lines side-by-side. This arrangement is shown as an illustrative example only. Other numbers and/or arrangements of word lines, global digit lines, local digit lines, memory cells, sense amplifiers, and so forth may be used in other example embodiments.

FIG. 5 is a top-down view of a memory quilt according to some embodiments of the present disclosure. The quilt 500 shows a view of an example quilt such as 202 of FIG. 2 and/or 400 of FIG. 4. The cross section 500 shows the plane 500 of FIG. 4. The quilt 500 represents a view along an example xy plane, showing a top layer of word lines extending horizontally in an x direction, global digit lines extending in a y direction, and local digit lines extending into the plane of the page in the z direction from the multiplexer circuits 510 where they intersect the GDL. The ‘top-down’ view of FIG. 5 shows a view of components which are not contained within a single plane. For example, the SWDs 520, sense amplifiers 530, multiplexer drivers 540, and the row decoders 543/545 and column decoders 533/535 may generally be located in a plane which is above the plane of the word lines, global digit lines, and multiplexers 510 in the z direction.

Certain components in the plane of the array, such as certain multiplexers 510, and portions of the global digit lines and word lines may be occluded by the sense amplifiers 530 and multiplexer drivers 540 which are above the memory patch. For example, the view of FIG. 5 shows global digit line pairs and multiplexer enable signal lines viewed through the spacer regions (e.g., 258 of FIG. 2) into the array patches (e.g., 252/254 of FIG. 2) below. The view of the components of the array patch visible in the view of FIG. 5 shows the multiplexer enable and bleed enable signal lines MUXE/BLDE and multiplexers 510 which run along a top of the array (in the z direction). The word lines may generally be stacked vertically below the MUXE/BLDE lines in the z direction, and the local digit lines and memory cells run below the multiplexers 510.

The quilt 500 shows two memory patches 512 and 514 (e.g., 252/254 of FIG. 2 and/or 404/404 of FIG. 4), a SWD/staircase region 522 (e.g., 172/182 of FIG. 1, 272/282 of FIG. 2, and/or 404 and 414 of FIG. 4), sense amplifier regions 532 and 534 (e.g., 174 of FIG. 1, 222/224 of FIG. 2, 310/311 of FIG. 3, and/or 422-424 of FIG. 4), multiplexer driver regions 542 and 544 (e.g., 176 of FIG. 1, 242 and 244 of FIG. 2, 314/316 of FIG. 3, and/or 452/454 of FIG. 4). Also shown in FIG. 5 are the local row decoders 543 and 545 (e.g., 162 of FIG. 1, and/or 262/264 of FIG. 2) and local column decoders (e.g., 164 of FIG. 1 and/or 232/234 of FIG. 2).

The SWD regions 522 includes SWD circuits 520. The sense amplifier regions 532 and 534 include sense amplifier circuits 530. The multiplexer driver regions 542 and 544 include multiplexer driver circuits 540. The array patches 512 and 514 each include a plurality of memory cells not shown in the view of FIG. 5 at the intersection of word lines and local digit lines. The ‘top’ of the local digit lines are selectively coupled through multiplexers 510 to one of the global digit lines of the associated global digit line pair. In the view of FIG. 5, the global digit line pairs are represented as a double line, one solid and one dotted, which are side-by-side in the xy plane. However, this is to help represent the paired nature of the GDLs. It does not necessarily represent the spatial arrangement of the GDL pair. For example, in some embodiments the two paired GDLs may be side by side in an xy plane, however in other embodiments the two paired GDLs may be above each other in a yz plane. Both GDLs of the pair are coupled to a same sense amplifier 530.

The sense amplifier circuits 530 in the sense amplifier regions 532 and 534 are coupled to both GDLs of a GDL pair. The GDL pair includes two GDLs labelled GDLT and GDLB. During an operation, the GDL of the GDL pair which is coupled to the active word line is used as a signal line and the other is used as a reference. For example, if the word line is coupled to GDLB, then the sense amplifier uses GDLT as a reference. Each patch includes 1024 GDL pairs, each coupled to one of 1024 sense amplifiers 530. In the example of FIG. 5, the sense amplifier regions 532 and 534 are arranged in grids with 4x256 sense amplifiers in the y and x directions respectively. For example, a first column includes SA0 coupled to GDLT0 and GDLB0, SA1 coupled to GDLT1 and GDLB1, SA2 coupled to GDLT2 and GDLB2, and SA3 coupled to GDLT3 and GDLB3. Vertical conductive elements (not shown in FIG. 5) extending in the z direction couple from the GDL pair up to the coupled sense amplifier.

The memory array includes 8000 word lines (not shown), WL0 to WL7999 . The word lines are arranged in 80 stacks of 100 word lines each. So the top row of word lines includes the visible word line (WL0) as well as 99 more word lines extending in the z direction into the plane from the point of view of the drawing. Multiplexer circuits 510 couple a ‘top’ of one or more LDLs to associated GDLs. The LDLs are arranged in a grid layout in an xy plane, with a row of the grid including 1024 LDLs along the x direction and a column of the grid including of 80 LDLs along the y direction. Each LDL is coupled through the multiplexer to one or other of the GDL pair. Which GDL of the GDL pair the LDLs are coupled to may change along the length of the GDL pair. The word lines WL extend from the first patch 512 to the second patch 514 under the SWD and staircase region 522.

The SWD and staircase region 522 includes a number of SWDs 520. There is a SWD for each word line. In this example there are 8000 SWDs 520, arranged in a grid of 80x100 SWDs in the yz plane. The SWDs 520 are arranged in 80 rows, with each row over a stack of WLs. Since the stacks of WLs are arranged with 100 WLs in each stack, each row of SWDs has 100 SWDs. Each SWD along a row has a conductive element running in the z direction down to the WL it is coupled to. The SWDs along a ‘row’ of the grid of SWDs are coupled to conductive elements of different lengths, since they are coupled to different depths (in the z direction) of word line. When activated by a row activation command, the SWD associated with the row address activates the associated word line.

The LDLs are coupled to the respective one of the GDL pair by a multiplexer circuit 510. The multiplexer circuit is generally positioned between a ‘top’ of the LDL in the z direction and the GDL. In the embodiment of FIG. 5, each multiplexer circuit 510 is associated with a pair of LDLs which are coupled in common through the multiplexer 510 to the associated one of the GDL pair. Other arrangements, such as a multiplexer for each LDL, a multiplexer for every 3 LDLs, etc., may be used in other example embodiments. A multiplexer driver circuit 540 is coupled by one or more signal lines extending in the x direction to a row of multiplexer driver circuits. The signal lines provide multiplexer enable signals MUXE, bleed enable signals BLDE or both. A row of multiplexers 510 may be coupled to a multiplexer driver in common.

In the embodiment of FIG. 5, the multiplexers 506 are arranged in an xy grid of 40 rows and 1024 columns. Each row of 1024 multiplexers is coupled in common to a multiplexer driver 540 in an associated one of the multiplexer driver regions 542-548. Accordingly, there are 40 multiplexer drivers 540 in each region 542 and 544. Each region 542-548 is associated with both of the regions 512 and 514. The region 542 is above the patch 512 and the region 544 is above the patch 514/

The multiplexer regions 542-548 each include multiplexer drivers 540 arranged in a column extending in y direction. Each multiplexer driver 540 may be associated with a row of multiplexers 510 extending in the x direction in the associated patch 512-518. In other words, each multiplexer driver 540 may be associated with one or more ‘stack’ of word. So, for example a first multiplexer driver MUXD0 may be associated with WL0 to WL199 since in the embodiment of FIG. 5 each multiplexer driver is associated with two stacks of word lines.

FIG. 5 also shows a pair of SCCAP regions 562 and 564 (e.g., 110 of FIG. 1) which are positioned on the edges of the memory quilt 500. The two SCCAP regions 562 and 564 are positioned on opposite edges of the memory quilt 500 in the x direction.

In an example operation, when a row activation command is received along with a row address, the SWD 520 associated with that address activates the associated word line. The associated multiplexer driver 540 activates the multiplexer circuit 510 so that the LDLs which intersect the active word line are coupled to the respective one of the pair of associated GDLs. When the word line is activated, the memory cells along that word line are coupled to the intersecting LDL and change a voltage of the LDL and the GDL that LDL is coupled to based on the stored charge. The SA coupled to that GDL senses this change by comparing the voltage on the GDL of the pair which is coupled to the word line to a pre-charge voltage on the other GDL of the pair and amplifies the difference during a read operation, or drives a new value onto the GDL pair in a write operation.

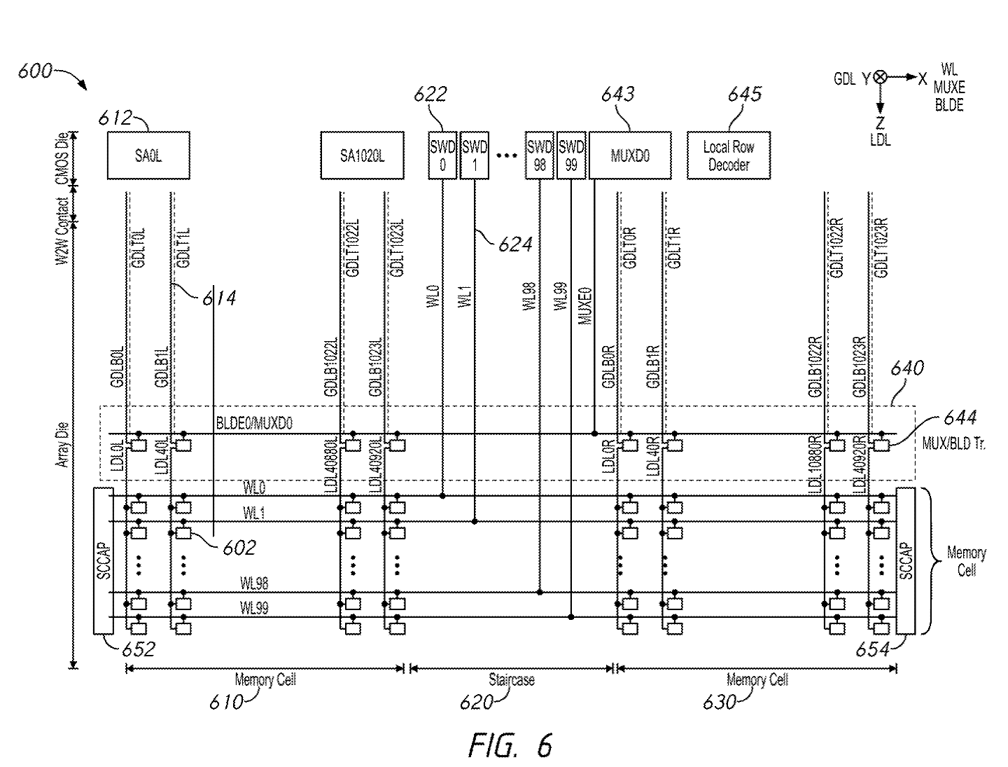

FIG. 6 is a cross sectional view of a memory device according to some embodiments of the present disclosure. The cross section 600 shows the plane 600 of FIG. 4. The cross section 600 represents a view along an example xz plane, showing word lines running horizontally along the x direction, local digit lines running vertically along a z direction, and global digit line pairs running into and out of the plane of the page along a y direction. Pairs of vertical conductive elements 614 are shown which runs ‘behind’ the plane of the cross section 600. The vertical conductive elements 614 are coupled to the sense amplifiers 612, which are positioned over the memory cells. The sense amplifiers 612 shown are in the sense amplifier portions which are positioned over the first memory patch 610 (e.g., sense amplifier regions 222 of FIG. 2, 310 of FIG. 3, 422of FIG. 4, and/or 532 of FIG. 5). Each sense amplifier 612 represents a ‘front’ sense amplifier in a column of sense amplifiers that extends out of the plane of the page.

The cross section 600 shows a first memory patch 610 (e.g., 252 of FIG. 2, 402 of FIG. 4, and/or 512 of FIG. 5), a staircase region 620 (e.g., 286 of FIG. 2, 410 of FIG. 4, and/or 522 of FIG. 5), and a second memory patch 630 (e.g., 254 of FIG. 2, 404 of FIG. 4, and/or 514 of FIG. 5). The cross section 600 shows a row a SWDs 622 associated with the WLs running through the patches 610 and 630, a multiplexer driver 643 (e.g., 176 of FIG. 1, 244 of FIG. 2, 316 of FIG. 3, 454 of FIG. 4, and/or 544 of FIG. 5) and local row decoder 645 (e.g., 162 of FIG. 1, 264 of FIG. 2, and/or 545 of FIG. 5).

Each word line is coupled to a respective SWD 622. For example, the cross section 600 shows SWD0 to SWD99, which are associated with WL0 to WL99 respectively. The SWDs 622 are located above in the z direction a staircase region 620 which is between the two patches 610 and 630 in the x direction. Each SWD 622 is coupled to a vertical conductive element 624 which extends in the z direction to the associated word line. Along a row of SWDs 622 like the one shown in FIG. 6, each of these vertical conductive elements 624 may be a different length, since the WLs are at different depths in the z direction. In the example layout of FIG. 6, the shortest vertical conductive element, coupled to the ‘top’ word line WL0, is on the far left, while the longest vertical conductive element, coupled to the ‘bottom’ word line WL99, is on the far right. Other arrangements may be used in other example embodiments.

The cross section 600 shows a ‘stack’ of word lines. In this case the word lines WL0 to WL99. A number of LDLs extend vertically in the z direction and memory cells 602 are coupled at the intersection of the LDLs and the WLs. In the example implementation, there are 81,920 LDLs per patch from LDL0 to LDL81919. Each LDL seen in the cross section 600 represents a ‘top’ of a stack of 80 LDLs which extend in the y direction. Thus the leftmost LDL in the patch 610 is LDL0L, the next LDL is LDL80L, the next is LDL160L and so forth up to LDL81840L. Similarly, the LDLs in the patch 620 are LDL0R up to LDL81919R.

The view of FIG. 6 includes digit line multiplexers 644 (e.g., 184 of FIG. 1, 318 of FIG. 3, and/or 510 of FIG. 5) in a digit line multiplexer region 640, and example multiplexer drivers 643. The multiplexers 644 selectively couple a set of LDLs to one of the GDLs of the respective GDLs. The multiplexer driver 643 is coupled to one or more signal lines extending the X direction which carry the multiplexer enable signal MUXE and the bleed enable signal BLDE which control the multiplexer region 640. For example, a first signal line couples the multiplexers 644 to MUXE and a second signal line couples the multiplexers 644 to BLDE. The multiplexer driver 643 represents a single driver in a multiplexer region. In particular, in the view 600 of FIG. 6, the driver is MUXD0, which provides signals MUXE0 and BLDE0. Additional drivers are stacked through the plane of the page in the y direction.

Responsive to a row activation command and a row address, local row decoder 645 selects a SWD 622 and multiplexer driver 643 based on the row address. For example, if the row address is associated with WL1, then MUXD0 will provide MUXE0, and the SWD1 622 will provide an enable signal WL1. The selected multiplexer driver activates a set of multiplexers 640 to couple the LDLs to one of the pair of GDLs. The selected SWD 622 activates the associated word line. This couples the memory cells 602 in the two patches 610 and 630 to be coupled to the LDLs which intersect that word line. The memory cells along the activated WL drive a voltage onto the intersecting LDLs, which then drive a voltage to the coupled GDL of the pair of GDLs through the activated multiplexers 644. The other LDLs, which are stacked in the Y direction and not visible in FIG. 6, are coupled to multiplexers which are coupled to different multiplexer drivers, and thus are not coupled to the GDLs. This may help reduce the capacitance of the GDL since each GDL is only coupled to the selected LDLs during a given operation a time.

In some embodiments, the SWDs 622 and multiplexer drivers 642 may be located in a CMOS die (e.g., 212 of FIG. 2B) while the memory cells, LDLs, WLs, and, if used multiplexer region 640 are located in an array die (e.g., 216 of FIG. 2B). The vertical elements 624, as well as the vertical portions of the GDLs may extend from the array die to the CMOS die and may include contacts between the two dice not shown in FIG. 6.

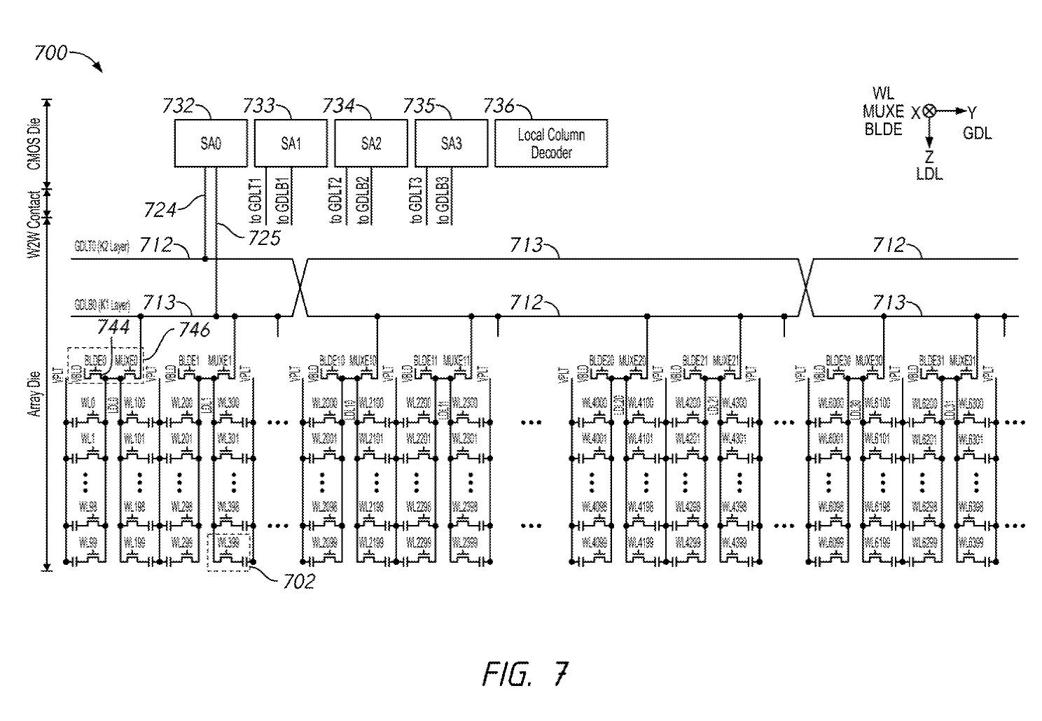

FIG. 7 is a cross sectional view of a memory device according to some embodiments of the present disclosure. The cross section 700 shows the plane 700 of FIG. 7. The cross section 700 represents a view along an example yz plane, showing a pair of global digit lines 712 and 713 running horizontally in the y direction, local digit lines running vertically in the z direction, and word lines running through the plane of the page in the x direction. The cross section 700 shows a portion of a first memory patch 710 (e.g., 252 of FIG. 2, 402 of FIG. 4, 512 of FIG. 5, and/or 610 of FIG. 6).

The cross section 700 intersects 8000 word lines in the memory patch. The word lines are organized in a grid in the yz plane with eighty columns in the z direction that have 100 word lines each. The 8000 word lines in the patch are organized in a grid of 80 memory cells in the x direction and 100 memory cells in the z direction. Each column of memory cells 702 is coupled to a local digit line, here labelled LDL0 to LDL79. In the embodiment of FIG. 7, the LDLs are paired and each pair LDLs is coupled in common to a multiplexer circuit 742. In some embodiments, each LDL may couple separately through a multiplexer to the GDL, rather than being paired.

Each memory cell 702 includes a capacitive element and a transistor. The gate of the transistor is coupled to the word line. One side of the capacitive element is coupled to a plate voltage VPLT, and the other side is coupled through the transistor to the LDL. When the word line is activated, the SWD drives a voltage along the word line which activates the transistor, coupling the capacitive element to the LDL.

The cross section 700 shows sense amplifiers 732, 733, 734, and 735. The sense amplifiers are part of a column of sense amplifiers in the y direction in a sense amplifier region. Each sense amplifier 732-735 is coupled to a different GDL pair. For example, the sense amplifier SA0 is coupled to GDLT0 712 and GDLB0 713, which form a sense amplifier pair. During an example operation, one of the two GDLs 712/713 is used to carry information, and the other is used as a reference. Along the length of the two GDLs, different LDLs are coupled to either the first or the second GDL of the pair. For example, as shown in FIG. 7, LDL0 to LDL9 may be coupled to GDLB0 713, LDL10 to LDL29 may be coupled to GDLT0 712, LDL30 to LDL49 may be coupled to GDLT0 712, and so forth.

In some example embodiments, such as the one shown in FIG. 7, the two GDLs in the pair may be stacked in the z direction, with one GDL over the top of the other. For example one GDL of the pair may be in one metal layer, and the other GDL may be in a second metal layer. In some embodiments, the GDLs of the pair may ‘twist’ or switch which GDL of the pair is in which metal layer. For example, in the embodiment of FIG. 7, GDLT0 is above GDLB0 when the pair runs above LDL0 to LDL9, but then the GDLs twist and GDLB0 is above GDLT0 from LDL10 to LDL19. This may be useful to allow the LDLs to always couple to the lower of the two GDLs (e.g., the GDL closer to the LDLs), but allow for changes in which LDLs are coupled to which of the GDL pair along its length. In this manner, portions of both of the GDLs 712 and 713 are in both metal layers.

The sense amplifiers 732-735 are shown positioned above at least some of the memory cells 702. Vertical conductive elements 724 and 725 couple the GDLs of the pair GDLB0 713 and GDLT0 712 up from the array die to the CMOS die. Since the vertical conductive elements are also over the array and the memory cells 702, the vertical conductive elements may run directly up from the array die to the sense amplifiers, without the need for additional horizontal (e.g., in the xy plane) routing. The vertical conductive elements 724 and 725 may have different lengths (e.g., analogous to the staircase region) since they run to different ‘depths’ along the z direction. FIG. 7 also shows a local column decoder 736 (e.g., 164 of FIG. 1, 232 of FIG. 2, and/or 533 of FIG. 5) which determines which GDL pair is coupled to the global input/output lines during an operation.

Each multiplexer circuit 742 includes a multiplexer transistor 746 and a bleed transistor 744. The bleed transistor 744 has a gate coupled to a bleed enable signal BLDE provided by a multiplexer driver and terminals coupled between a ground voltage VBLD and the pair of local digit lines. The multiplexer transistor 746 has a gate coupled to a multiplexer enable signal MUXE and terminals coupled between one of the GDLs and the pair of LDLs.

During an example operation, if a row address is received associated with the first patch 710, then the multiplexer driver which controls the LDL which intersects the WL activates the multiplexer transistor 746 by providing MUXE, and each of the other multiplexer drivers provide BLDE to their respective bleed transistor 744 to couple those LDLs to VBLD and prevent them from floating. For example, if the row address indicates WL 101, which intersects LDL0, then MUXD0 provides MUXE0, which couples LDL0 to GDLB0 713. The other LDLs receive BLDE at an active level, (e.g., BLDE1 to BLDE39) which couples those LDLs to VBLD instead of to the respective GDL.

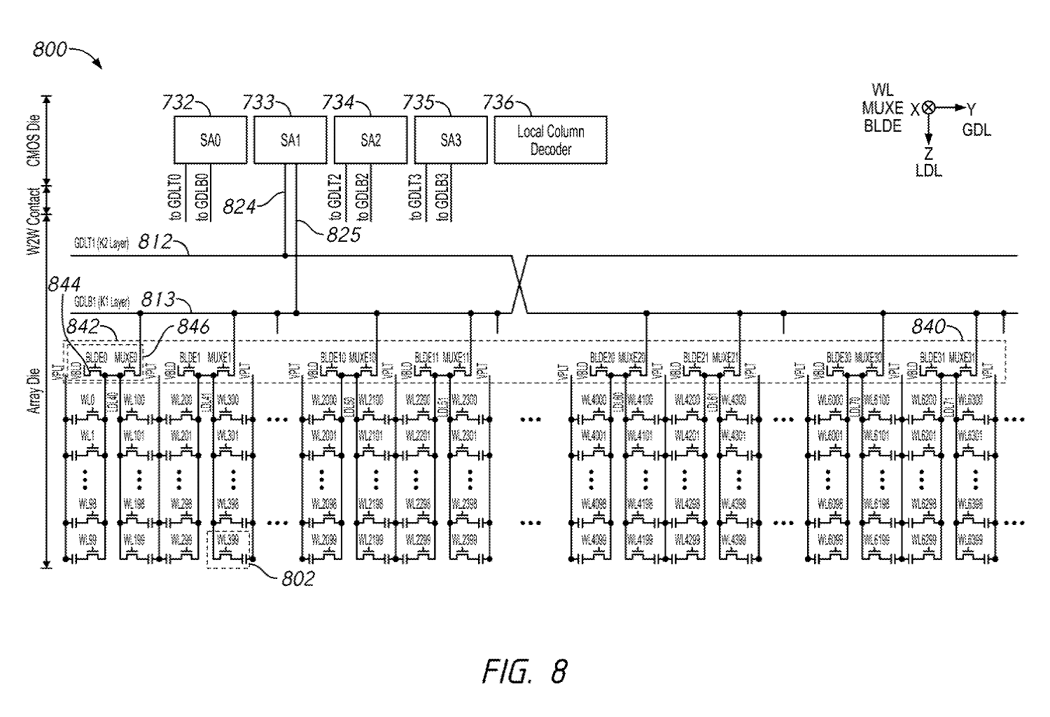

FIG. 8 is a cross sectional view of a memory device according to some embodiments of the present disclosure. The cross section 800 is generally similar to the cross section 700 of FIG. 7, except that the cross section 800 is offset from the cross section 700 in the +x direction and includes the adjacent pair of GDLs GDLT1 812 and GDLB1 813. For the sake of brevity certain details which were already previously described with respect to FIG. 7 are not repeated again with respect to FIG. 8. FIG. 8 uses similar reference numbers for similar components, and reuses the same reference numbers as FIG. 7 for components which extend through the x direction to be visible in both cross sections 700 and 800.

In the cross-section 800 of FIG. 8, a different GDL pair is shown. The GDL pair GDLT1 812 and GDLB1 813 are coupled along vertical elements 824 and 825 (respectively) to SA1 733. Also, the GDL pair of GDLT/B1 twists in different places than the GDL pair of GDLT/B0 of FIG. 7. For example, the GDL pair GDLT1 812 and GDLB1 813 twist between LDL59 and LDL60 instead of between LDL9 and LDL10.

FIG. 9 is a block diagram of an example cross section of a 3D memory patch with refresh groups according to an embodiment of the present disclosure. The 3D memory patch 900 may implement one or more of the memory patches described herein such as in the memory array 180 of FIG. 1, 252/254 of FIG. 2, 300 of FIG. 3, 600 of FIG. 6, 700 of FIG. 7, and/or 800 of FIG. 8. FIG. 9 shows an xz slice of the device, similar to the view of FIG. 6. FIG. 9 shows a simplified block view where memory cells 902 (e.g., 302 of FIG. 3, 602 of FIG. 6, 702 of FIG. 7, and/or 802 of FIG. 8) are represented as boxes in an array. The rows represent memory cells along a word line, with the columns representing a stack of memory cells through a depth of the array along a local digit line. The xz slice represents a ‘stack’ 910 of word lines. The depth of the memory cells in the array (e.g., the z coordinate of the memory cell) may generally referred to as a ‘tier’ 920 of the memory cells. For example, the word lines (and memory cells) along an xy slice through the 3D memory array may all be referred to as being part of the same tier and thus may all have the same depth. The word lines side by side in a same tier may be referred to as ‘row’ of word lines, while the word lines in different tiers of a stack may be a stack or column of word lines.

Due to the process of manufacturing the 3D memory device, the capacitance of the memory cells may vary based on what tier 920 they are in. Memory cells 902 in the highest tier of the stack 910 (e.g., closest to the CMOS die, not shown) have a lower capacitance than memory cells 902 at the lowest tier 920 of the stack (e.g., furthest from the CMOS die, not shown). The retention time of a memory cell, the length of time it can go between refresh operations without losing data, is generally proportional to the capacitance. Accordingly, the retention time of a memory cell varies as a function of what tier the memory cell is in, with higher tiers having a shorter retention time and lower tiers having a longer retention time. The memory device may divide the memory tiers 920 of the array into two or more refresh groups, which can be refreshed at different rates, in order to take advantage of the fact that deeper memory cells will have longer retention times. The different groups are determined based on a position (e.g., a depth) of the word lines in their respective stacks 910.

The example of FIG. 9 shows N tiers of memory cells and M different refresh groups. For example, if there are 75 memory cells, and 3 refresh groups, then each refresh group would have 25 tiers of memory cells, with Group0 including tiers 0 to 24, Group1 including tiers 25 to 49, and Group2 including tiers 50 to 74. In such an example implementation, Group1 would be refreshed more often than Group2, and Group2 would be refreshed more often than Group3. The different rates at which the Groups are refreshed relative to each other may be determined by the lowest capacitance in each group. Since the lowest capacitance will generally be the uppermost memory cell, the relative refresh rates may generally be determined by the capacitances of the uppermost memory cell in each group. In the example implementation with 75 memory cells and 3 refresh groups, the relative refresh rates may, for example, be determined by the capacitances of the memory cells in tier 0, tier 25, and tier 50.

The different refresh rates may allow for better retention characteristics for the memory cells with lower retention characteristics (e.g., in the upper groups). This may be accomplished by lowering the amount of refreshes performed on the groups with better retention characteristics (e.g., the lower groups) during a refresh period while raising the amount of refreshes performed on the groups with worse retention characteristics (e.g., the higher groups) during a refresh period so that the overall refreshes ‘average out’. For example, a middle group may refresh at the rate expected by a refresh specification of the memory device, while an upper group may refresh at the normal rate +X% and a lower group may refresh at the lower rate -X%. In this way the overall refreshes match the expected rate, but the upper group has an improved refresh characteristic.

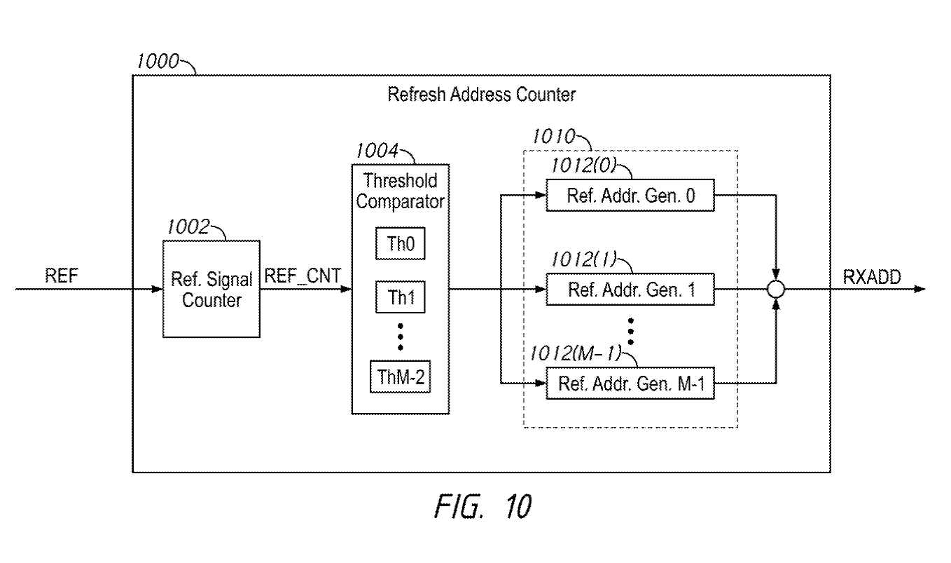

FIG. 10 is a block diagram of refresh address counter with tier based refresh grouping according to some embodiments of the present disclosure. The refresh address counter 1000 may, in some embodiments, implement the refresh counter 130 of FIG. 1. The refresh address counter 1000 receives a refresh signal REF and provides a refresh address RXADD. The memory device refreshes one or more word lines associated with the refresh address RXADD as part of a refresh operation. The refresh signal REF may represent an refresh command issued by a controller or a self-refresh signal issued by a self-refresh oscillator. In some embodiments, the refresh signal REF may be an internal refresh signal generated in response to a refresh command or self-refresh signal.

The refresh address counter 1000 includes a refresh signal counter circuit 1002, a threshold comparator 1004, and a set of refresh address generator circuits 1010. The set 1010 includes a refresh address generator circuit 1012 for each of the refresh groups. Each refresh address generator circuit 1012 generates refresh addresses associated with the tiers within the associated group. In an example implementation, the refresh address generator may generate addresses for the word lines of a stack and then move on to the adjacent stack. For example, using an example of three refresh groups and 75 tiers of word lines, where word lines are numbered from top to bottom, the first group may include word lines with addresses such as 0 to 24, 75 to 99, 150 to 174 and so forth, the second group may include word lines with addresses such as 25 to 49, 100 to 124, 175 to 199 and so forth, and the third group may include word lines with addresses such as 50 to 74, 125 to 149, and 200 to 224. Other ways of organizing the addresses may be used in other example embodiments. Each refresh address generator circuit 1012 me be implemented a counter circuit that counts through the address values in its range of tiers and then, once it reaches the end, recycles back to the beginning of the range.

The refresh address counter 1000 refreshes the different refresh groups a different amount. This in turn, leads to different rates of refreshing in aggregate, even in situations when the individual refresh operations are happening at a relatively steady rate. The refresh signal REF may be expected to be received a set number of times within a refresh period. The number of times the refresh signal REF is received may be based on a refresh specification of the memory. Rather than evenly distribute the refresh signals REF across the memory address space, different proportions of the refresh signals REF are assigned to different refresh groups. For example, if there are 3 refresh groups, then a word line in the first group may be refreshed responsive to 47% of the refresh signals, a word line in the second group may be refreshed responsive to 33% of the refresh signals, and a word line in the third group may be refreshed responsive to 20% of the refresh signals. This distribution is given as an example only, and other distributions may be used in other example embodiments. By changing what percent of refresh signals are used for what refresh groups, the overall rate at which the different rates are refreshed may be changed.

The refresh signal counter is a counter circuit which updates a refresh count signal REF_CNT responsive to the refresh signal REF being received. For example, the refresh signal counter 1002 may increment the refresh count signal REF_CNT each time REF is received. The refresh count signal REF_CNT may be a multi-bit signal, such as a binary number, which represents the count of the refresh signal REF. The refresh signal counter circuit 1002 may reset or ‘roll over’ the count REF_CNT when it reaches the expected number of times REF will be received in a refresh period. For example, if REF is expected 8192times in a refresh period, then the refresh counter circuit 1002 will count REF_CNT from 0 to 8191 and then reset back to 0.

The threshold comparator circuit 1004 compares REF_CNT to a number of thresholds. The thresholds may be used to determine which refresh address generator circuit 1012 of the set 1010 to activate. For example, if REF_CNT is below a first threshold Th0, then the first refresh address generator circuit Ref. Addr. Gen. 0 will be activated to provide RXADD. If REF_CNT is above Th0 but below a second threshold Th1 then Ref. Addr. Gen. 1 will be activated to provide RXADD. This pattern continues up to the final threshold ThM-2, where if REF_CNT is greater than ThM-2, then the final refresh address generator Ref. Addr. Gen. M-1 will be activated to provide RXADD. By adjusting the levels of the thresholds relative to the overall range of values of REF_CNT, different proportions of the refresh signal REF may be used for different refresh groups.

In an example implementation, if there are J refresh commands (or self-refresh signals) expected per refresh period, then the thresholds may be set based on a multiplier of J. For example, if it desired for the first group to take up X% of the refresh commands, then the first threshold may be set as X*J. In an example with three refresh groups, where it is desired to split the refreshes with 47% going to the first group, 33% to the second group, and 20% to the third group, and there are 1000 refresh commands per refresh period, then the first threshold Th0 may be set to 470 and the second threshold Th1 to 800. Accordingly, the first 470 refresh signals REF will cause the refresh address RXADD to be generated for a first refresh tier group, the next 330 will cause the refresh address RXADD to be generated for a second refresh tier group, and the next 200 refresh signals REF will cause the refresh RXADD to be generated for a third refresh tier group. After that, the refresh address counter 1002 will reset and refreshes will begin again for the first refresh tier group.

While the refresh commands REF may be unevenly distributed between refresh address generators, the different tier groups may generally evenly divide the number of tiers of word lines. In this way, some of the word lines of the upper refresh tier groups may be refreshed more than once in a refresh period, while some word lines in a lower refresh tier may skip being refreshed during a given refresh period. In some embodiments, the different tier groups may have equal numbers of word lines. In some embodiments, the number of word lines in each group may be different, for example if the number of word lines is not evenly divisible by the number of tier groups.

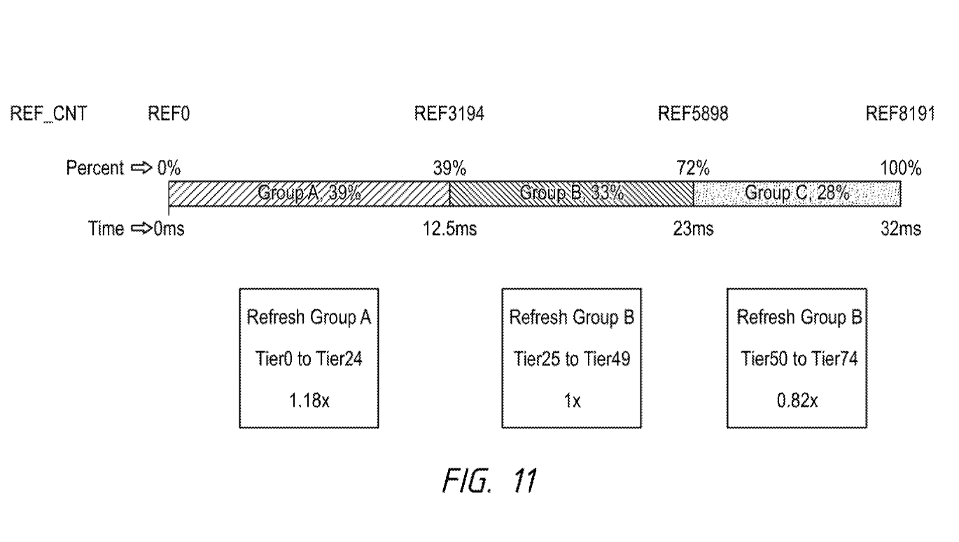

FIG. 11 is a chart showing an example implementation of different refresh rates for different tier groups according to some embodiments of the present disclosure. FIG. 11 shows an example implementation of a particular way of splitting refresh operations between different tier refresh groups. The chart 11 may represent an example implementation using the refresh counter 1000 of FIG. 10 in some embodiments.

In the example implementation of FIG. 11, there are 75 tiers of memory cells, which are divided into three refresh groups, here labelled A, B, and C from top to bottom. Refresh Group A includes the memory cells in tiers 0 to 24, Refresh Group B includes the memory cells in tiers 25 to 49, and refresh group C includes the memory cells in tiers 50 to 74. In the example implementation, a refresh cycle is 32 ms long, and the memory expects 8192 refresh signals REF (e.g., 8192 refresh commands or 8192 self-refresh commands). In the example of FIG. 11, Group A is refreshed for 39% of the refresh signals, Group B is refreshed for 33% of the refresh signals, and Group 3 is refreshed for 28% of the refresh signals. The values in FIG. 11 are all for example only, and other values may be used in other example implementations.

The different amounts of time each group is refreshed may be determined based, at least in part, on a ‘worst case’ retention time within each group. In these three groups that will be the retention times of tiers 0, 25, and 50. Since the retention time is based on the capacitance, the capacitances of the tiers 0, 25, and 50 are compared. In this example, the capacitance of tier25 is 18% greater than the capacitance of tier0, and the capacitance of tier 50 is 16% greater than the capacitance of tier 25. Since the 18% difference is greater, that can be used to set the different refresh group thresholds. In order to have the three groups average out, the word lines are Group A are refreshed at +18% compared to an even distribution of refreshes and the word lines of Group B are refreshed -18% compared to an even number of refreshes. In other words, 1.18/3 or 39% of the refresh signals are used to refresh group A, 1/3 or 33% of the refresh signals are used to refresh Group B, and 0.82/3 or 28% of the refresh signals are used to refresh group C. By multiplying these rations by the number of refresh operations per refresh period (8192 in this example), the different thresholds can be found. For example, word lines in Group A will be refreshed while REF_CNT is at or below 3194, word lines in Group B will be refreshed while REF_CNT is between 3194 and 5898 and word lines in Group 3 will be refreshed while REF_CNT is above 5898 until it resets at 8181 back to 0.

Since each of the refresh groups contains the same number of word lines, and the number of refresh operations, when evenly divided is expected to refresh each word line exactly once, some word lines in Group A will be refreshed twice, while some word lines in Group B will not be refreshed in a refresh period. For example, the word lines in Group A are refreshed 1.18 times per refresh period. That means that of the word lines in Group A, 18% of them will be refreshed twice in a given refresh period. In a similar fashion, 18% of the word lines in Group C will not be refreshed in a given refresh period. Over multiple refresh periods this will lead to a higher rate of refreshes for the word lines of Group A than the word lines of Group C.

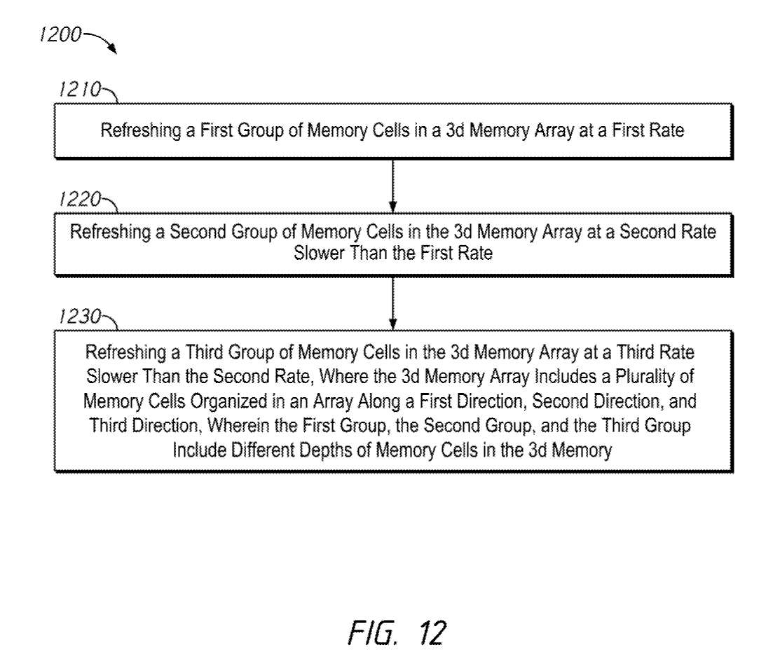

FIG. 12 is a flow chart of a method of refreshing a 3D memory device with tier based refresh groups according to some embodiments of the present disclosure. The method 1200 may, in some embodiments, be performed by one or more of the apparatuses and/or systems described herein. Such as any of the 3D memory devices, or portions thereof, of FIGS. 1-8. The method 1200 may be implemented by the refresh groups of FIG. 9, the chart 1100 of FIG. 11, and/or the refresh address counter circuit 1000 of FIG. 10.

The method 1200 includes block 1210, which describes refreshing a first group of memory cells in a 3D memory array at a first rate, block 1220 which describes refreshing a second group of memory cells in the 3D memory array at a second rate slower than the first rate, and block 1230 which describes refreshing a third group of memory cells in the 3D memory array at a third rate slower than the second rate. The three groups each include different tiers of memory cells in the 3D memory array (e.g., tiers 920 of FIG. 9). For example, the 3D memory array includes memory cells organized in a first direction (x), a second direction (z) and a third direction (y), with the group determined by different depths of memory cells along the second direction. The first group may be a first set of tiers, the second group may be a second set of tiers, and the third group may be a third set of tiers. The first set of tiers may be above the second set of tiers and the second set of tiers may be above a third set of tiers. For example, the first set of tiers may be closest to the global digit lines and the third set of tiers may be furthest from the global digit lines.

The method 1200 may include providing the 3D memory array. The 3D memory array includes word lines extending in a first direction (x), local digit lines extending in a second direction (z) and global digit lines extending in the third direction (y). The first group of memory cells are at a first range of depths along the second direction, the second group of memory cells are at a second range of depths along the second direction, and the third group of memory cells are at a third range of depths along the second direction.

In some embodiments, the second rate may match an expected rate of refresh operations from a specification of the memory. For example, the second rate may be such that the second group of memory cells are refreshed once per refresh period. The first rate may be such that at least some of the first group of memory cells are refreshed more than once per refresh period. The third rate may be such that at least some of the third group of memory cells are not refreshed in a refresh period.

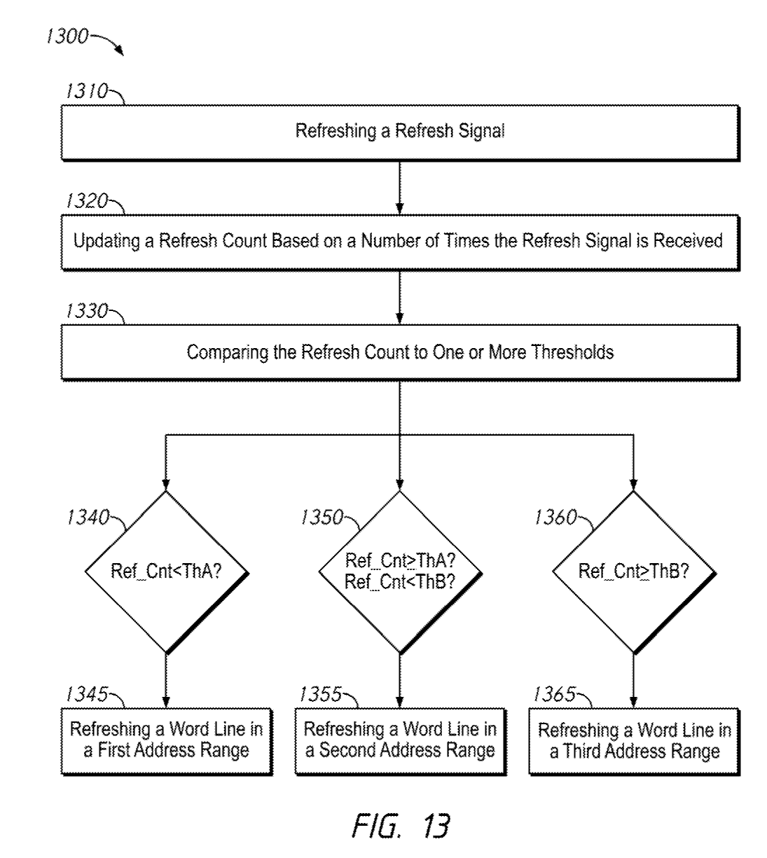

FIG. 13 is a flow chart of a method of tier based refreshing according to some embodiments of the present disclosure. The method 1300 of FIG. 13 may be used to implement the method 1200 of FIG. 12 in some embodiments. For example, the method 1300 may be performed by a refresh address counter circuit such as 1000 of FIG. 10. The method 1300 may generally be described with respect to an embodiment with 3 refresh groups, however a method similar to 1300 may be used for more or fewer refresh groups.

The method 1300 may generally begin with block 1310 which describes receiving a refresh signal. The refresh signal may represent a refresh command, a self-refresh oscillator signal, an internal signal generated responsive to the refresh command and/or the self-refresh oscillator signal, or combinations thereof.

Block 1310 may be followed by block 1320, which describes updating a refresh count based on a number of times the refresh signal is received. For example, a refresh signal counter circuit (e.g., 1002 of FIG. 10) may update the refresh count. The method 1300 may include incrementing the refresh count responsive to the refresh signal. The method 1300 may include counting the refresh count up to a maximum value and then resetting back to a initial value (e.g., 0). The maximum value may be based on an expected number of refresh signals (e.g., an expected number of refresh commands) in a refresh period.

Block 1320 may generally be followed by block 1330 which describes comparing the refresh count to one or more thresholds. For example, a threshold comparator circuit (e.g., 1004 of FIG. 10) may perform the comparing. The method 1300 may include selecting one of the groups to refresh based on the comparison between the refresh count and the thresholds. Blocks 1340-1365 describe an example implementation for the selecting based on 3 refresh groups.

Blocks 1340 and 1345 describe refreshing a word line in a first refresh range (e.g., in the first group of memory cells) if the refresh count is less than a first threshold. Blocks 1350 and 1355 describe refreshing a word line in a second refresh range (e.g., in the second group of memory cells) if the refresh count is between the first threshold and a second threshold. Blocks 1360 and 1365 describe refreshing a word line in a third address range (e.g., in the third group of memory cells) if the refresh count is greater than the second threshold.

The method 1300 may include setting the thresholds based on a lowest capacitance memory cell in each of the groups of memory cells. The lowest capacitance memory cell may generally be the memory cells in the uppermost tier (e.g., the least depth) of each group.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a 3D memory array comprising a plurality of word lines extending in a first direction, with the plurality of word lines organized in stacks along a second direction and rows in a third direction;
a refresh address counter circuit configured to refresh the plurality of word lines, wherein the plurality of word lines are divided into different groups, and wherein each of the groups is refreshed at a different rate, wherein each group is defined by a range of depths of the plurality of word lines in their respective stacks.

2. The apparatus of claim 1, wherein the 3D memory array further comprises:
a plurality of local digit lines extending in the second direction;
a plurality of memory cells disposed at the intersections of the plurality of local digit lines and the plurality of word lines;
a plurality of global digit lines extending in the third direction, wherein each of the plurality of global digit lines is coupled to a set of the plurality of local digit lines.

3. The apparatus of claim 1, wherein the refresh address counter circuit is configured to refresh at least some of the word lines of at least one of the groups more than once per refresh period and refresh at least some of the word lines of at least one other of the groups less than once per refresh period.

4. The apparatus of claim 3, wherein the refresh address counter circuit is configured to refresh at the word lines of a further at least one of the groups once per refresh period.

5. The apparatus of claim 1, wherein the refresh address counter circuit comprises:
a refresh signal counter circuit configured to update a refresh count when a refresh signal is received;
a threshold comparator circuit configured to compare the refresh count to one or more thresholds;
a plurality of refresh address generator circuits each associated with one of the groups, wherein the threshold comparator circuit activates one of the refresh address generator circuits based on the comparison of the refresh count to the one or more thresholds.

6. The apparatus of claim 5, wherein the one or more thresholds are set based on capacitances of memory cells along the word lines of the groups.

7. The apparatus of claim 1, wherein the 3D memory array is in a first die, and wherein the refresh address counter circuit is in a second die stacked on top of the first die, wherein the groups which are closer to the top are closer to the second die than the groups which are lower.

8. An apparatus comprising:
a 3D memory array comprising a plurality of word lines organized in at least one stack, the plurality of word lines including:
a first set of word lines at a first range of depths in the at least one stack;
a second set of word lines at a second range of depths in the at least one stack; and
a third set of word lines at a third range of depths in the at least one stack; and
a refresh address counter circuit comprising:
a refresh signal counter circuit configured to update a refresh count based on a number of times a refresh signal is received;
a threshold comparator circuit configured to compare the refresh count to a first threshold and a second threshold; and
a first refresh address generator configured to generate a refresh address associated with the first set of word lines when activated;
a second refresh address generator configured to generate a refresh address associated with the second set of word lines when activated;
a third refresh address generator configured to generate a refresh address associated with the third set of word lines when activated,
wherein the threshold comparator circuit is configured to activate the first refresh address generator when the refresh count is below the first threshold, activate the second refresh address generator when the refresh count is between the first threshold and the second threshold and activate the third refresh address generator when the refresh count is above the third threshold.

9. The apparatus of claim 8, wherein the first set of word lines, the second set of word lines, and the third set of word lines include an equal number of word lines, wherein the first refresh address generator, the second refresh address generator, and the third refresh address generator are activated different numbers of times during a refresh cycle.

10. The apparatus of claim 8, wherein the refresh address counter circuit is configured to refresh the second set of word lines once per refresh period, refresh at least some of the first set of word lines more than once per refresh period, and refresh at least some of the third set of word lines less than once per refresh period.

11. The apparatus of claim 8, wherein the plurality of word lines extend in a first direction, the 3D memory array further comprising:
a plurality of local digit lines extending in a second direction orthogonal to the first direction;
a plurality of memory cells disposed at the intersections of the plurality of word lines and the plurality of local digit lines; and
a plurality of global digit lines extending in a third direction orthogonal to the first direction and the second direction, wherein each of the plurality of global digit lines is coupled to a set of the plurality of local digit lines,
wherein the depth in the stack is based on a position of the word line along the second direction.

12. The apparatus of claim 8, wherein the 3D memory array is in a first die and the refresh address counter circuit is in a second die stacked on top of the first die.

13. The apparatus of claim 8, further comprising a plurality of memory cells positioned along the plurality of word lines, wherein a capacitance of the plurality of memory cells varies based on the depth of the word line.

14. The apparatus of claim 13, wherein the first threshold and the second threshold are set based on the capacitance of the memory cells.

15. A method comprising:
refreshing a first group of memory cells in a 3D memory array at a first rate;
refreshing a second group of memory cells in the 3D memory array at a second ratee slower than the first rate;
refreshing a third group of memory cells in the 3D memory array at a third rate slower than the second rate, wherein the 3D memory array includes a plurality of memory cells organized in an array along a first direction, second direction, and third direction, wherein the first group, the second group, and the third group include different depths of memory cells 3D>3D memory array.

16. The method of claim 15, further comprising providing the 3D memory array with a plurality of word lines extending in a first direction, a plurality of local digit lines extending in a second direction orthogonal to the second direction, a plurality of memory cells are disposed at the intersections of the plurality of word lines and the plurality of local digit lines, and a plurality of global digit lines extending in a third direction orthogonal to the first and the second direction, wherein each of the plurality of global digit lines is coupled to a set of the plurality of local digit lines, and wherein the first group of memory cells are at a first range of depths along the second direction, the second group of memory cells are at a second range of depths along the second direction, and the third group of memory cells are at a third range of depths along the second direction.

17. The method of claim 15, further comprising:
refreshing at least some of the first group of memory cells more than once in a refresh period;
refreshing the second group of memory cells once in the refresh period;
refreshing at least some of the third group of memory cells less than once in the refresh period.

18. The method of claim 15, further comprising:
receiving a refresh signal;
updating a refresh count based on a number of times the refresh signal is received;
comparing the refresh count to a first threshold and a second threshold; and
selecting the first group of memory cells, the second group of memory cells or the third group of memory to refresh based on the comparison of the refresh count to the plurality of thresholds.

19. The method of claim 18, further comprising:
refreshing the first group of memory cells if the refresh count is less than the first threshold;
refreshing the second group of memory cells if the refresh count is between the first threshold and the second threshold; and
refreshing the third group of memory cells if the refresh count is above the second threshold.

20. The method of claim 18, further comprising setting the first threshold and the second threshold based on a lowest capacitance memory cell of the first group, a lowest capacitance memory cell of the second group, and a lowest capacitance memory cell of the third group.
